(19) United States
(12) Patent Application Publication
(10) Pub. No.: US 2018/0040461 A1
(43) Pub. Date: Feb. 8, 2018

(54) APPLICATION OF DIODE BOX TO REDUCE CRAZING IN GLASS COATINGS

(71) Applicant: Advanced Energy Industries, Inc., Fort Collins, CO (US)

(72) Inventors: Joshua Brian Pankratz, Fort Collins, CO (US); Douglas R. Pelleymounter, Northfield, MN (US); Uwe Krause, Dresden (DE)

(21) Appl. No.: 15/226,463

(22) Filed: Aug. 2, 2016

(51) Int. Cl. H01J 37/34; C03C 17/09; H01J 37/32; C23C 14/34; C23C 14/18

(52) U.S. Cl. CPC H01J 37/347; C23C 14/34; C23C 14/185; H01J 37/32899; H01J 37/32733; C03C 17/09; C03C 2218/154

(57) ABSTRACT

Systems, methods, and apparatus are disclosed for reducing crazing in thin film stacks deposited on large area substrates such as glass, for instance architectural glass. Crazing can occur once a conductor-insulator-conductor series of films have been deposited, thereby effectively forming a capacitor, and where the substrate spans multiple deposition chambers such the coupling between chambers can cause the effective capacitor voltage to breakdown the insulator layer between the two conductor layers. The resulting crazing can be reduced if not eliminated through the grounding of outputs of an AC power supply that assists in deposition of one of the conductor layers. The grounding is via rectified channels, such as diodes, or series of diodes such that the outputs of the AC power supply are precluded from falling below ground potential.

### BACKGROUND

### Field of the Disclosure

The present disclosure relates generally to substrate coating, and more specifically to systems, methods, and apparatus that reduce crazing in thin film coatings applied to substrates, for instance glass substrates.

### Description of Related Art

Glass sheets and other substrates can be coated with a stack of transparent, metal and dielectric-containing films to vary the optical properties of the coated substrates. Particularly desirable are coatings characterized by their ability to readily transmit visible light while minimizing the transmittance of other wavelengths of radiation, especially radiation in the infrared spectrum. These characteristics are useful for minimizing radiative heat transfer without impairing visible transmission. Coated glass of this nature is useful as architectural and automotive glass.

For instance, coatings having the characteristics of high visible transmittance and low emissivity typically include one or more infrared-reflective films and two or more antireflective transparent dielectric films. The infrared-reflective films, which are typically conductive metals such as silver, gold, or copper, reduce the transmission of radiant heat through the coating. The transparent dielectric films are used primarily to reduce visible reflection, to provide mechanical and chemical protection for the sensitive infrared-reflective films, and to control other optical coating properties, such as color. Commonly used transparent dielectrics include oxides of zinc, tin, and titanium, as well as nitrides of silicon, chromium, zirconium, and titanium. Low-emissivity coatings are commonly deposited on glass sheets through the use of well-known magnetron sputtering techniques.

For instance, one or more layers of a metal such as silver or copper can be deposited to change the reflectance and absorbance characteristics of a glass pane. Reference is made to U.S. Pat. No. 4,462,884 (Gillery, et al.) with respect to the production of silver/copper films by cathode sputtering, and to U.S. Pat. No. 4,166,018 (Chapin) with respect to the method of coating a substrate utilizing a cathode sputtering technique involving a magnetic field to improve the sputtering efficiency. Alternatively, a mirror can be manufactured by applying a reflective coating to a glass substrate using magnetron sputtering techniques of the type described in Chapin, U.S. Pat. No. 4,166,018.

The technique, sometimes referred to as a magnetron sputtering technique, involves the formation of a plasma which is contained by a magnetic field and which serves to eject metal atoms from an adjacent metal target, the metal atoms being deposited upon an adjacent surface such as the surface of a glass pane. When sputtering is done in an atmosphere of an inert gas such as argon, the metal alone is deposited whereas if sputtering is done in the presence of oxygen, e.g., in an atmosphere of argon and oxygen, then the metal is deposited as an oxide. Magnetron sputtering techniques and apparatuses are well known and need not be described further.

Plasma C.V.D. involves decomposition of gaseous sources via a plasma and subsequent film formation onto solid surfaces, such as glass substrates. The thickness of the resulting film can be adjusted by varying the speed of the substrate as it passes through a plasma zone and by varying the power and gas flow rate within each zone.

Sputtering techniques and equipment are well known in the art. For example, magnetron sputtering chambers and related equipment are commercially available from a variety of sources (e.g., Leybold, BOC Coating Technology, Advanced Energy). Useful magnetron sputtering techniques and equipment are also disclosed in U.S. Pat. No. 4,166,018, issued to Chapin, the entire teachings of which are incorporated herein by reference.

To achieve the multi-layer glass coatings described above, processing lines are used where a slab of glass (e.g., up to twelve feet on a side) is passed through a plurality of plasma deposition chambers continuously moving on a conveyor belt or other substrate support. Each deposition chamber can include on or more sputtering targets and a power supply such that as the glass passes through each chamber, a different thin film layer is deposited. Given a series of dozens of chambers, a slab of glass can be quickly and homogeneously coated with dozens of thin film layers.

In some cases, especially where layers of dielectrics and conductors are used (e.g., of oxide-metal-oxide glass coatings by Cardinal Glass Industries and exemplified by U.S. Pat. No. 5,302,449), crazing near the edges of the deposited layers has been witnessed, and such problems have plagued manufacturers since at least the 1970's. While there have been various attempts over the last half century to understand the source of crazing and try to reduce it, no viable solutions have been found. Thus, in most cases, glass manufacturers ignore the crazing, which tends toward edges of the glass, especially where the crazing is less than one inch in length (since the outer one inch of architectural glass is typically covered by the window frame).

There is therefore a need in the art for systems and methods of glass coating that reduce crazing of sputtered thin films.

### SUMMARY

One aspect of this disclosure can be described as a substrate coating system to reduce crazing of thin films deposited on the substrate via plasma deposition in a series of plasma deposition chambers. The substrate coating system can include first, second, third, and fourth plasma deposition chambers, a first power supply, a second AC power supply, a third DC power supply, a fourth AC power supply, a substrate support, and first and second rectified channels to ground. The first plasma deposition chamber can be configured to deposit a first conductor onto the substrate. The second plasma deposition chamber can be configured to deposit an insulator onto the substrate one or more layers above the first conductor. The third plasma deposition chamber can be configured to deposit a second conductor onto the substrate one or more layers above the insulator. The fourth plasma deposition chamber can be configured to deposit a third conductor onto the substrate one or more layers above the second conductor. The first power supply can be coupled to the first plasma deposition chamber. The second AC power supply can be coupled to the second plasma deposition chamber. The third DC power supply can be coupled to the third plasma deposition chamber. The fourth AC power supply can be coupled to the fourth plasma deposition chamber. The substrate support can be arranged throughout the first, second, third and fourth plasma deposition chambers and can be configured to move the substrate through the substrate coating system while at least two of the first, second, third, and fourth plasma deposition chambers simultaneously deposit respective ones of the first conductor, the insulator, the second conductor, and the third conductor on the substrate. The first rectified channel to ground can be coupled between a first output of the fourth AC power supply and the ground. The second rectified channel to ground can be coupled between a second output of the fourth AC power supply and ground.

Another aspect of the disclosure can be characterized as a substrate coating system to reduce crazing of thin films deposited on the substrate via plasma deposition in a series of plasma deposition chambers. The system can include first, second, and third plasma deposition chambers, a first power supply, a second AC power supply, and first and second rectified channels to ground. The first plasma deposition chamber can be configured to deposit a first conductor onto the substrate. a second plasma deposition chamber configured to deposit an insulator onto the substrate one or more layers above the first conductor. The third plasma deposition chamber can be configured to deposit a second conductor onto the substrate one or more layers above the insulator. The first power supply can be coupled to the first plasma deposition chamber. The second AC power supply can be coupled to the second plasma deposition chamber. The third AC power supply can be coupled to the third plasma deposition chamber. The first rectified channel to ground can be coupled between a first output of the third AC power supply and ground. The second rectified channel to ground can be coupled between a second output of the third AC power supply and ground.

Yet another aspect of the disclosure can be characterized as a method of reducing crazing of thin films in a substrate coating system. The method can include providing a first plasma deposition chamber configured to deposit a first conductor onto the substrate. The method can also include providing a second plasma deposition chamber configured to deposit an insulator onto the substrate one or more layers above the first conductor, and providing a third plasma deposition chamber configured to deposit a second conductor onto the substrate one or more layers above the insulator. The method can yet further include providing a first power supply coupled to the first plasma deposition chamber, and providing a second AC power supply coupled to the second plasma deposition chamber. The method can further include providing a third AC power supply coupled to the third plasma deposition chamber. The method can yet further include coupling a first output of the third AC power supply to ground via a first rectifying circuit, and coupling a second output of the third AC power supply to ground via a second rectifying circuit.

### BRIEF DESCRIPTION OF THE DRAWINGS

FIG. 1 shows a section of a substrate coating system or processing line, comprising a plurality of plasma deposition chambers, each configured to deposit either an insulator or a conductor;

FIG. 2 shows another section of a substrate coating system or processing line, and in particular a system having an arrangement of thin films where pairs of conductor layers are separated by sets of three-layer insulator regions;

FIG. 3 shows the same substrate coating system, but with the substrate in a different position during movement along the processing line;

FIG. 4 shows another view of a substrate coating system or processing line where a number of insulator and conductor layers are being deposited, and three different positions of a substrate where crazing has been observed;

FIG. 5 illustrates a subsection of a substrate coating system having a plurality of deposition chambers arranged in a processing line, where the instant substrate coating system includes at least one deposition chamber for sputtering an insulator;

FIG. 6 illustrates a subsection of a substrate coating system having a plurality of deposition chambers arranged in a processing line, where the instant substrate coating system includes at least one deposition chamber for sputtering a conductor;

FIG. 7 illustrates a subsection of a substrate coating system having a plurality of deposition chambers arranged in a processing line, where the instant substrate coating system includes at least one deposition chamber for sputtering a conductor;

FIG. 8 illustrates another substrate coating system showing one of the many combinations of deposition chambers and arrangements of chambers that can be implemented;

FIG. 9 shows the system of FIG. 8 with the substrate in an alternative position that has been known to lead to crazing;

FIG. 10 illustrates another substrate coating system having a plurality of deposition chambers, a bipolar DC power supply for helping to deposit conductor, and a pump adjacent to a chamber with the bipolar DC power supply;

FIG. 11 illustrates yet another substrate coating system having a plurality of deposition chambers, a bipolar DC power supply for helping to deposit conductor, and a pump adjacent to a chamber with the bipolar DC power supply;

FIG. 12 illustrates yet another substrate coating system having a plurality of deposition chambers;

FIG. 13 shows the substrate coating system of FIG. 12, but where the substrate is in an earlier position in the substrate coating system where crazing is often observed;

FIG. 14 illustrates a portion of a substrate coating system having a conduction deposition chamber coupled to a bipolar DC power supply, wherein the power supply's outputs (or leads to electrodes in the chamber) each include a rectified channel to ground;

FIG. 15 illustrates an alternative embodiment of the rectified channels to ground seen in FIG. 14;

FIG. 16 illustrates an alternative embodiment of the rectified channels to ground seen in FIGS. 14 and 15;

FIG. 17 illustrates another portion of a substrate coating system having a conduction deposition chamber coupled to a bipolar DC power supply, wherein the power supply's outputs (or leads to electrodes in the chamber) each include a rectified channel to ground;

FIG. 18 illustrates another portion of a substrate coating system where two conductor deposition chambers are arranged adjacent to each other, the first coupled to a DC power supply, and the second coupled to a bipolar DC power supply having outputs that each include a rectified channel to ground;

FIG. 19 illustrates another portion of a substrate coating system having a conduction deposition chamber coupled to a bipolar DC power supply, wherein the power supply's outputs (or leads to electrodes in the chamber) each include a rectified channel to ground;

FIG. 20 illustrates another portion of a substrate coating system having a first conductor deposition chamber, a first insulator deposition chamber, a pump, a second conductor deposition chamber, a third conductor deposition chamber, a second pump, and a second insulator deposition chamber;

FIG. 21 illustrates a substrate coating system to reduce crazing of thin films deposited on a substrate via plasma deposition in a series of plasma deposition chambers;

FIG. 22 illustrates a substrate coating system to reduce crazing of thin films deposited on a substrate via plasma deposition in a series of plasma deposition chambers;

FIG. 23 illustrates a substrate coating system to reduce crazing of thin films deposited on a substrate via plasma deposition in a series of plasma deposition chambers;

FIG. 24 illustrates another portion of a substrate coating system;

FIG. 25 illustrates a method of reducing crazing of thin films during processing in a substrate coating system;

FIG. 26A shows a voltage plot for the floating anode of a DC power supply before the crazing problem was solved; and

FIG. 26B shows a voltage plot for the floating cathode of a DC power supply before the crazing problem was solved.

### DETAILED DESCRIPTION

The word “exemplary” is used herein to mean “serving as an example, instance, or illustration.” Any embodiment described herein as “exemplary” is not necessarily to be construed as preferred or advantageous over other embodiments.

For the purposes of this disclosure, a plasma sputtering chamber and a plasma deposition chamber will be used interchangeably.

For the purposes of this disclosure a substrate can be a glass substrate, such as architectural glass, display technology glass (e.g., laptop and TV screens), or any other substrate upon which thin film coatings can be deposited.

For the purposes of this disclosure, an insulator can include dielectrics and oxides among other insulators.

For the purposes of this disclosure, a conductor can include metals and other conductive materials, as well as semiconductors. For instance, the conductor layers described below can include metals such as silver, aluminum, or tungsten, to name three non-limiting examples.

For the purposes of this disclosure, crazing (or lighting arcs) is the defect in conductive thin film layers caused when one or more dielectric insulating layers between the conductive thin films breaks down. Further, the defect may be unseen when measured differentially by power supplies involved in the process.

As noted above, many attempts have been made to understand and reduce crazing. For instance, some have theorized that strong electric fields in the coatings are the cause of the crazing, and have therefore beveled the edges of the glass before coating in order to reduce the electric field at the edges. However, such beveling adds significant cost to the manufacturing process in terms of both labor and mechanical setup. Additionally, beveling is not 100% effective.

Others have tried grounding the glass during processing by providing a ground line between a top surface of the glass and ground. However, the grounding lead or probe caused defects in the coatings and poor deposition characteristics and was thus unsatisfactory.

Yet others, noting that crazing is less common after a chamber has been cleaned, have attempted to perform frequent chamber cleanings. However, such frequent cleanings require the chamber vacuum to be removed and then returned thus causing unacceptable loss in throughput.

Still others have looked at a differential voltage between electrodes in a single plasma deposition chamber, but have been unable to observe any electrical anomalies correlated with arcing (which is believed to be responsible for the crazing). Some, believing that coupling between nearby processing chambers in the processing line leads to crazing, have worked to isolate plasmas in adjacent chambers (e.g., by providing a separate vacuum pump for each chamber). While this may reduce electrical coupling between plasmas in adjacent chambers, crazing continues to be seen.

Thus, no viable solutions have been found in almost a half century of work on this plaguing challenge.

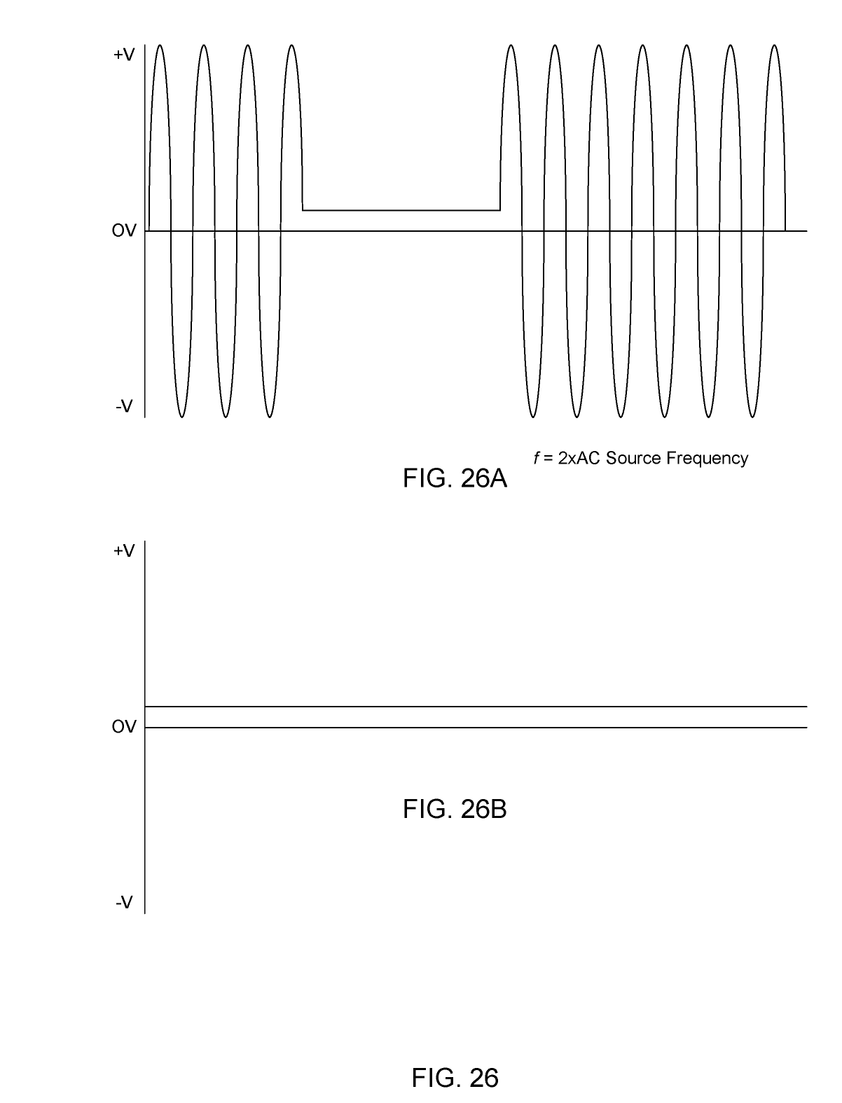

Instead, industry leaders have, for over forty years, accepted that 20% or more of coated glass output would include crazing without finding a solution with sufficiently-low cost to make it commercially viable. This filing marks a departure from this long period of stagnant innovation, as the inventors recognized that if differential voltage measurements of electrodes in a given chamber did not reveal any correlation with the supposed arcs, perhaps measurements referenced to ground would. When such measurements were made on the electrodes of a DC power supply in the processing chain, the inventors observed a non-DC voltage (see FIG. 26A). While the cathode continued to show the expected DC waveform of the DC power supply (see FIG. 26B), the anode showed a rectified AC waveform having the same AC characteristics as a nearby AC power supply (see FIG. 26A). This was the first time that anyone in the history of glass coating had observed an electrical characteristic that possibly showed the source of the arcing that was believed to be behind the crazing. The inventors reasoned that the unexpected waveform was being coupled into the DC anode via the glass itself. In particular, they reasoned that when at least two conductive layers were deposited on the glass separated by one or more dielectric layers, these three layers formed a capacitor that coupled AC signals from an AC power supply in a first processing chamber, through the glass, and into the DC anode. As this AC signal coupled through the glass, the change in voltage was accentuated by the sharp corners of the glass thus creating an electric field spike large enough to break down the dielectric and cause an arc and crazing in the thin film stack spreading inward from the sharp glass edges.

With this hypothesis in hand, the inventors attempted to filter the coupling of AC power through the glass by grounding the anode and cathode of the AC power supply that appeared to be coupling AC through the glass. In particular, they coupled the leads to the electrodes to ground via a diode box having two chains of series-connected diodes (the diode number and size can be selected to withstand a maximum cathode voltage, cathode current, and frequency of the AC power). A diode box can include two inputs, each one coupled to a different one of the electrodes or leads of the AC power supply, and each one providing a rectified path to ground for the outputs of the AC power supply. Implementing this diode box indirectly ties the anode of the DC power supply to ground and prevents the anode from rising above a threshold such as 50V, and preferably keeps the anode of the DC power supply within a window such as 20V to 50V. Excessive voltages (e.g., over 50V) on the anode of the DC power supply are thought to be responsible for the dielectric breakdown voltage and arcing.

When a diode box was used in this manner on an AC power supply coupled to a plasma deposition chamber that deposited a conductive layer, the crazing was completely eliminated (for the first time since the problem arose in the 1970's).

While such diode boxes had previously been affixed to the electrodes or leads of AC power supplies in the processing line, those same boxes had radically increased crazing when applied to DC power supplies in the processing line. DC supplies were traditionally used to form conductive layers in the thin film stack. However, recent trends have seen AC supplies also used relative to deposition of conductive layers. Because the diode boxes had worsened the crazing problem when applied to DC supplies used to deposit conductive layers, no one had thought to implement a diode box on AC supplies used to deposit conductive layers—the long-held expectation was that crazing would be greatly increased by such attempts. The inventors, having noted the unusual coupled signal in the DC power supply, bucked these long-held notions and affixed a diode box on an AC supply used to deposit conductive layers. To their surprise, the crazing was eliminated.

The solution described above and further detailed below will aid in the adoption of bipolar DC power supplies for conductor layer deposition via dual magnetron sputtering of large area glass coating applications, where such adoption is currently stymied by crazing.

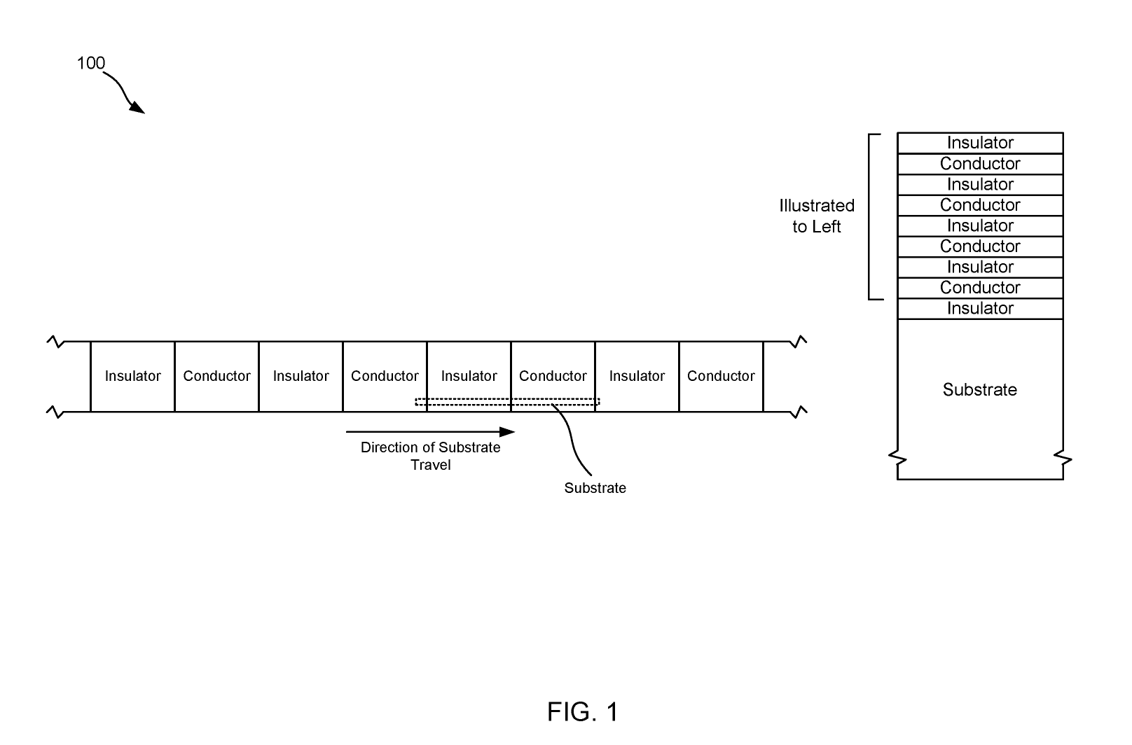

FIGS. 1-4 provide further details regarding the crazing challenge. FIG. 1 shows a section of a substrate coating system or processing line, comprising a plurality of plasma deposition chambers, each configured to deposit either an insulator or a conductor. A substrate, such as a slab of architectural glass, is shown in the system. One can see that the substrate may be sized such that it spans multiple plasma deposition chambers and therefore may see deposition of multiple layers simultaneously. The chambers to the left of FIG. 1 deposit the first or lowest layers, while chambers to the right continuously deposit additional layers atop those deposited by previous chambers.

A thin film stack is illustrated to the right of FIG. 1 and shows a substrate, such as glass, with nine thin films deposited thereon. Eight of the chambers that deposited the thin films in the stack are illustrated in the system diagram on the left of FIG. 1. The sizing and shapes of the thin films and the substrate are not to scale and not intended to be limiting, as they merely provide a visualization of the thin film stack if the substrate were cut down the middle and the films were revealed. In practice, the thin films wrap around edges of the substrate and thus only the uppermost layer is typically visible within cutting the substrate.

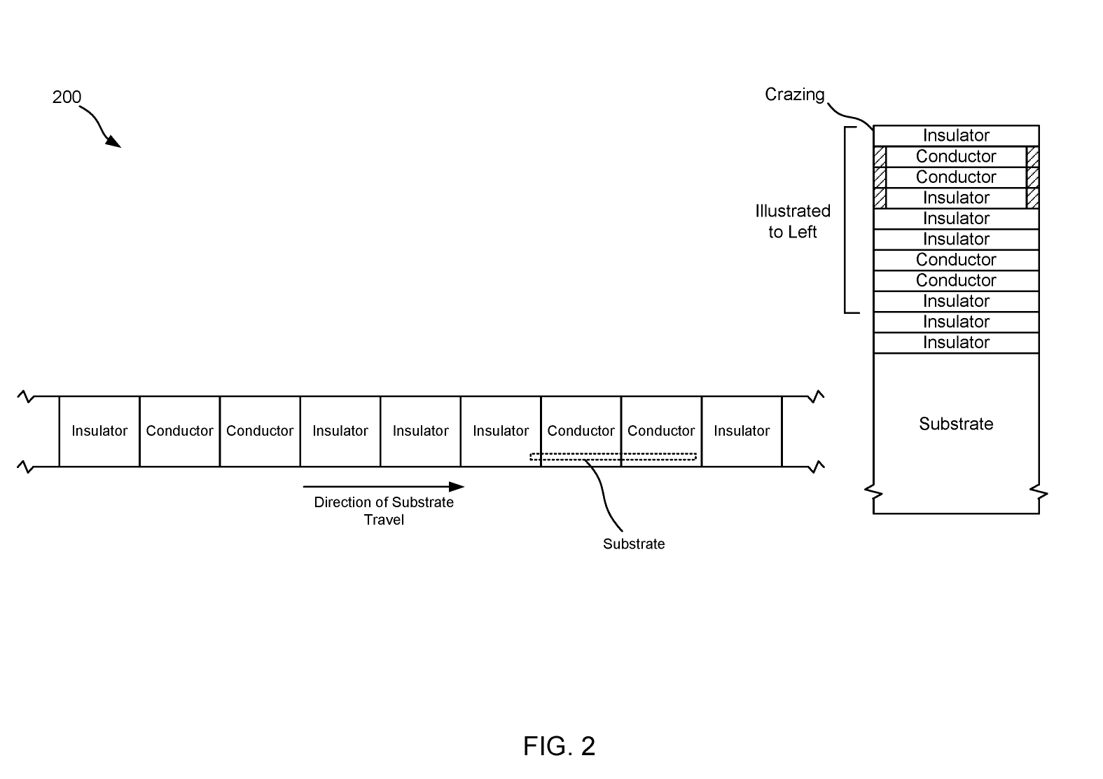

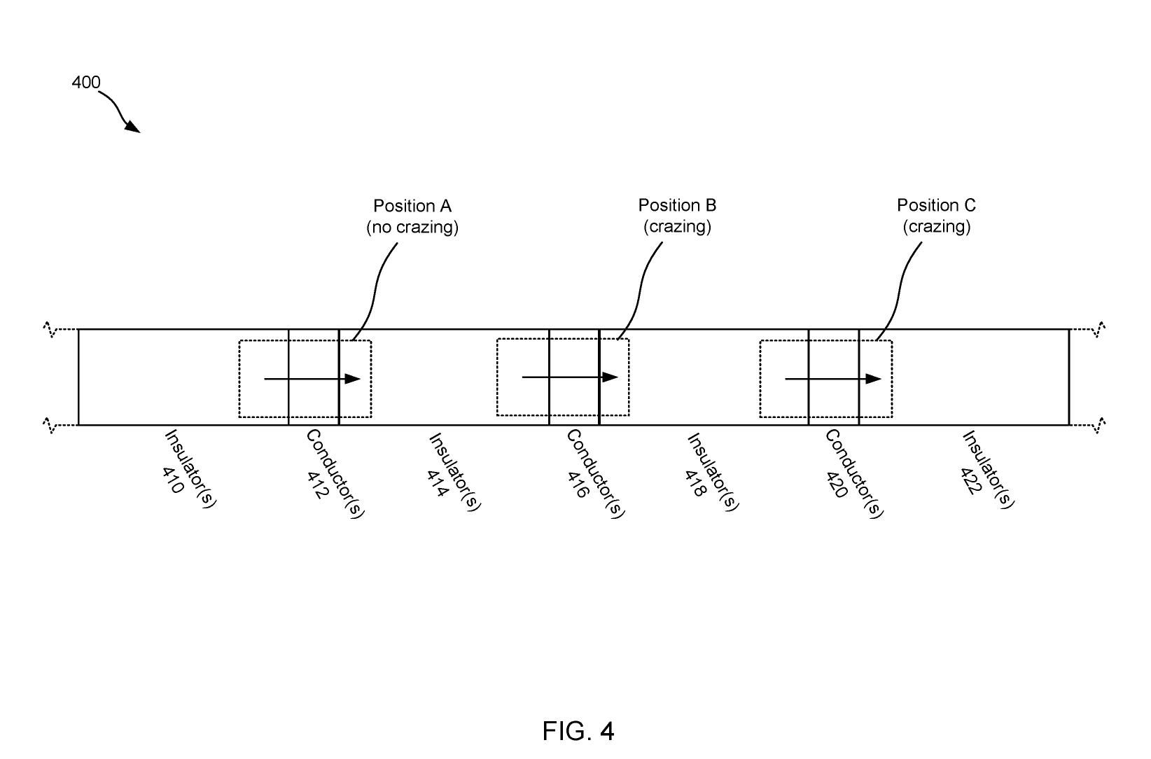

FIG. 2 shows another section of a substrate coating system or processing line, and in particular a system having an arrangement of thin films where pairs of conductor layers are separated by sets of three-layer insulator regions. In some embodiments, the conductors can be different materials. In some embodiments, the insulator layers can be of the same material, and depending on the deposition process, can therefore form one homogenous layer (see, e.g., FIG. 4). Therein, such a thin film stack could be described as having an insulator-conductor-conductor-insulator-conductor-conductor-insulator pattern despite multiple chambers being used to form each of the insulator layers.

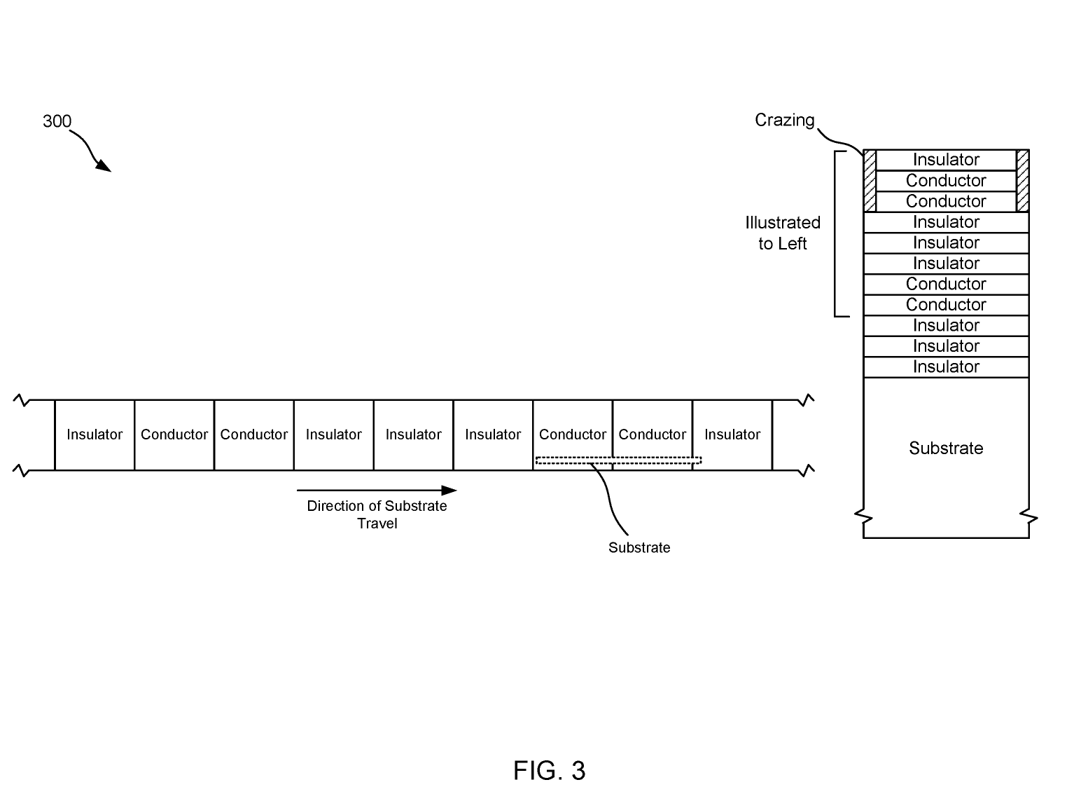

FIG. 3 shows the same substrate coating system, but with the substrate in a different position during movement along the processing line. In particular, the inventors found that crazing can occur where the substrate is being processed by an insulator chamber, a conductor chamber, and a further conductor chamber (FIG. 2) or by a conductor chamber, a conductor chamber, and an insulator chamber (FIG. 3). The thin film stacks to the right of both figures show the layers that typically see crazing given these chamber arrangements and substrate positions. To note, in both FIGS. 2 and 3, crazing occurs after at least two conductor layers separated by at least one insulator layer have been deposited. The inventors believe that this arrangement of films can be modeled as a capacitor, and the buildup of charge between the two conductive plates (i.e., the at least two conductor layers) is what eventually overwhelms the insulator between them and leads to breakdown, arcing, and crazing. The inventors have even seen up to 200 μF capacitance between metal layers in a thin film stack deposited on a glass substrate.

FIG. 4 shows another view of a substrate coating system or processing line where a number of insulator and conductor layers are being deposited, and three different positions of a substrate where crazing has been observed. To note, since multiple chambers can be used to form a single insulator layer, these multiple chambers have been abstracted into a single box labeled “insulator(s)”. Further, where multiple conductor chambers are implemented in a row, those have been abstracted into single boxes labeled “conductor(s).” One of skill in the art will therefore appreciate that FIG. 4 shows embodiments where one or more plasma deposition chambers are arranged in series to deposit one larger insulator layer, and where one or more plasma deposition chamber are arranged in series to deposit adjacent conductor layers.

Position A shows one position of the substrate during processing, wherein an insulator layer (or layers) has been deposited followed by one or more adjacent conductor layers, and one or more additional insulator layers atop the one or more adjacent conductor layers. At this early stage in the processing line, crazing is typically not observed. One explanation is that the one or more adjacent conductor layers do not effectively form one plate of a parallel plate capacitor and therefore the charge buildup that leads to crazing is not possible yet.

Position B shows one position of the substrate during processing, wherein an insulator layer (or layers) 410, followed by one or more adjacent conductor layers 412, a second insulator layer (or layers) 414, a second set of one or more adjacent conductor layers 416, and a third insulator layer (or layers) 418 have been deposited on the substrate. In this situation, a capacitor has effectively been deposited on the substrate, and the conductor(s) 412 and 416 act as the two plates of the capacitor. Charge is able to build up on these conductor layers 412 and 416 that can be great enough to cause breakdown of the insulator(s) 414 and result in crazing.

Position C is similar to position B in that at least one if not two capacitors have effectively been created in the thin film stack. Here, the second capacitor can comprise the conductor(s) 416, the insulator(s) 418, and the conductor(s) 420.

It should be noted that in positions B and C, crazing often does not occur until the substrate has moved into the first of one or more chambers for depositing an insulator (e.g., 418 or 422). The reason has to do with coupling between a power supply associated with the insulator chamber and power supplies associated with the conductor chambers.

In sum, one sees that crazing typically occurs after at least two conductor layers have been deposited where the two conductor layers are separated by at least one insulator layer. Further, the start of deposition of the next insulator atop the last conductor may be required for crazing to occur.

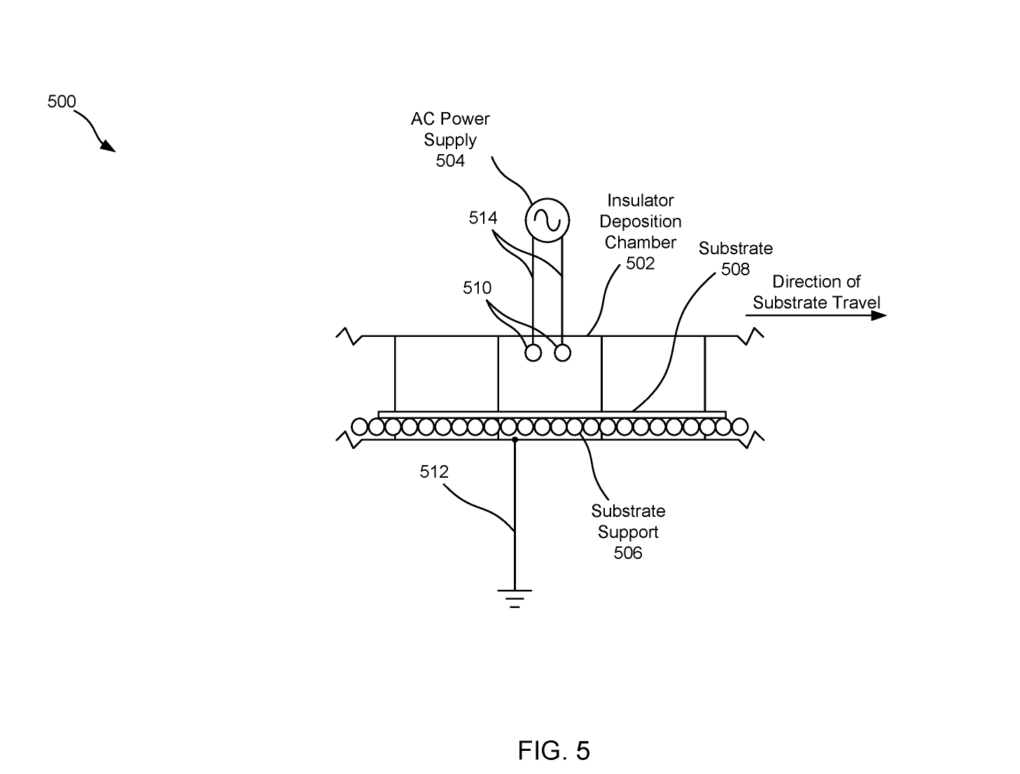

FIG. 5 illustrates a subsection of a substrate coating system 500 having a plurality of deposition chambers arranged in a processing line, where the instant substrate coating system 500 includes at least one deposition chamber for sputtering an insulator. The insulator deposition chamber 502 is coupled to an AC power supply 504, including AC and bipolar DC power sources (such as the Crystal AC Power Supply and Ascent DMS manufactured by Advanced Energy, Fort Collins, Colo.). The system 500 also shows two other non-defined deposition chambers on either side of the insulator deposition chamber 502 that can be configured to deposit insulators, conductors, or other materials. System 500 includes a substrate support 506, such as conveyor rollers, that is arranged through at least the insulator deposition chamber 502 as well as other chambers in the substrate coating system 500. The substrate support 506 is configured to pass or convey a substrate 508 through at least the insulator deposition chamber 502 as well as other chambers in the system 500 such that the chambers can continuously deposit thin films as the substrate 508 passes through each chamber. The substrate 508 is often, but not always, sized such that it spans more than one chamber at a time. Here, the substrate 508 spans five chambers and is therefore seeing deposition of five different thin film layers at the same time. However, each chamber is likely depositing films at different locations on the substrate 508 at any given moment. In some case, there may be ‘overspray’ from one chamber to the next, so the previous statement may not always be true.

The AC power supply 504 can be coupled to two or more electrodes 510. Where two electrodes are used, as illustrated, the pair of electrodes 510 can be an anodeless pair—meaning that each electrode 510 plays the role of cathode and anode, depending on the AC cycle of the AC power supply 504. The AC power supply 504 can be coupled to and provide power to the electrodes 510 via connections 514. The connections 514 can be embodied in a single cable, such as a coaxial cable or triaxial cable, or in pairs of cables, wires, or leads.

The AC power supply 504, connections 514, and electrodes 514 can take any shape, form, and arrangement, as such modifications will not affect the outcome of this disclosure. For instance, the electrodes 510 can be cylindrical or cubic, to name just two non-limiting examples. The electrodes 510 can also be arranged and in contact with sides of the insulator deposition chamber 502, or can be largely separated from the chamber 502 walls as illustrated (of course some support structure that couples to the chamber 502 walls will typically be used, but the majority of the electrodes 510 are not in contact with the chamber 502 in this embodiment).

The AC power supply 504 is used with the insulator deposition chamber 502 to deposit insulating or dielectric material (e.g., various oxides) in an insulator or dielectric thin film on the substrate 508. Given the illustrated chamber position, the insulator or dielectric film will be deposited above one or more other films and below one or more other films. However, in other embodiments, the insulator deposition chamber and its AC power supply 504 can be arranged in other positions in the substrate coating system 500, for instance at the front or back of the processing line such that the insulator of dielectric layer is the bottom or top layer of a thin film stack on the substrate 508.

The AC power supply 504 and its electrodes 510 are illustrated as electrically floating, or floating, and therefore the voltage on the electrodes 510 and output by the AC power supply 504 is not referenced to ground. In other embodiments, the AC power supply 504 can be referenced to ground. The illustrated insulator deposition chamber 502 is grounded via grounding connection 512. Where the chambers in the substrate coating system 500 are conductively coupled, only a single grounding connection 512 for the entire system 500 is needed, although more than this can be implemented.

The substrate support 506 can be grounded, or electrically connected to the chambers or the grounding connection 512. Alternatively, the substrate support 506 can be floating. In this and subsequent figures, the substrate support 506 is assumed to be grounded.

In this and subsequent figures, the substrate 508 direction of travel is to the right of the page, however this is illustrative only, and one of skill in the art will recognize that these figures are equally applicable to substrates passing from right to left.

Although not illustrated, the insulator deposition chamber 502 also includes devices and components commonly seen in plasma deposition chambers such as magnets and sputtering targets. For simplicity, these common and well-known features have not been illustrated and will not be discussed.

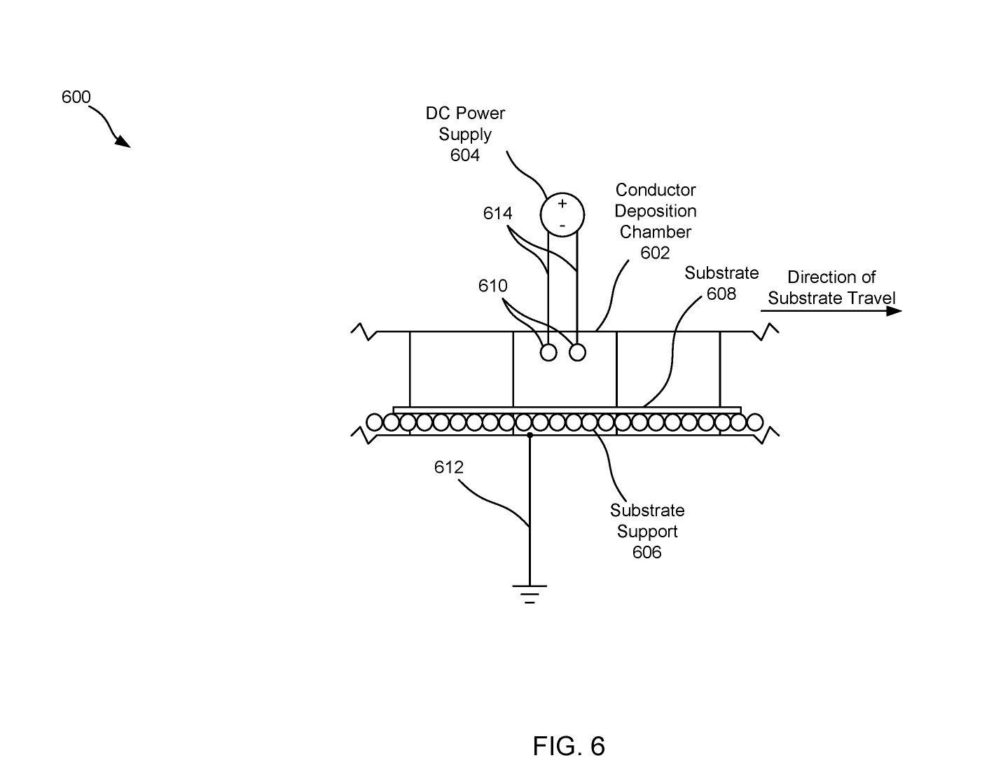

FIG. 6 illustrates a subsection of a substrate coating system 600 having a plurality of deposition chambers arranged in a processing line, where the instant substrate coating system 600 includes at least one deposition chamber for sputtering a conductor. The conductor deposition chamber 602 is coupled to a DC power supply 604 (such as the AMS or Pinnacle DC Power Supplies manufactured by Advanced Energy, Fort Collins, Colo.). The system 600 also shows two other non-defined deposition chambers on either side of the conductor deposition chamber 602 that can be configured to deposit insulators, conductors, or other materials. System 600 includes a substrate support 606, such as conveyor rollers, that is arranged through at least the conductor deposition chamber 602 as well as other chambers in the substrate coating system 600. The substrate support 606 is configured to pass or convey a substrate 608 through at least the conductor deposition chamber 602 as well as other chambers in the system 600 such that the chambers can continuously deposit thin films as the substrate 608 passes through each chamber.

The DC power supply 604 can be coupled to two electrodes 610 as illustrated. However, in other embodiments, only a single electrode may be implemented. Alternatively, more than two electrodes can be used. As illustrated, the electrodes 610 are floating. In other embodiments, one of the electrodes can be coupled to the chamber 602 or to ground such that the cathode is referenced to ground rather than the floating arrangement that is illustrated. The DC power supply 604 can be coupled to and provide power to the electrodes 610 via connections 614. The connections 614 can be embodied in a single cable, such as a coaxial cable or triaxial cable, or in pairs of cables, wires, or leads.

The DC power supply 604, connections 614, and electrodes 614 can take any shape, form, and arrangement, as such modifications will not affect the outcome of this disclosure. For instance, the electrodes 610 can be cylindrical or cubic, to name just two non-limiting examples. The electrodes 610 can also be arranged and in contact with sides of the insulator deposition chamber 602, or can be largely separated from the chamber 602 walls as illustrated (of course some support structure that couples to the chamber 602 walls will typically be used, but the majority of the electrodes 610 are not in contact with the chamber 602 in this embodiment).

The DC power supply 604 is used with the insulator deposition chamber 602 to deposit conductor (or conducting or conductive) material in a conductor thin film on the substrate 608. Given the illustrated chamber position, the conductor film will be deposited above one or more other films and below one or more other films. However, in other embodiments, the conductor deposition chamber and its DC power supply 604 can be arranged in other positions in the substrate coating system 600, for instance at the front or back of the processing line such that the conductor layer is the bottom or top layer of a thin film stack on the substrate 608.

The DC power supply 604 and its electrodes 610 are illustrated as electrically floating, or floating, and therefore the voltage on the electrodes 610 and output by the DC power supply 604 is not referenced to ground. In other embodiments, the DC power supply 604 can be referenced to ground. The illustrated conductor deposition chamber 602 is grounded via grounding connection 612. Where the chambers in the substrate coating system 600 are conductively coupled, only a single grounding connection 612 for the entire system 600 is needed, although more than this can be implemented.

The substrate support 606 can be grounded, or electrically connected to the chambers or the grounding connection 612. Alternatively, the substrate support 606 can be floating. In this and subsequent figures, the substrate support 606 is assumed to be grounded.

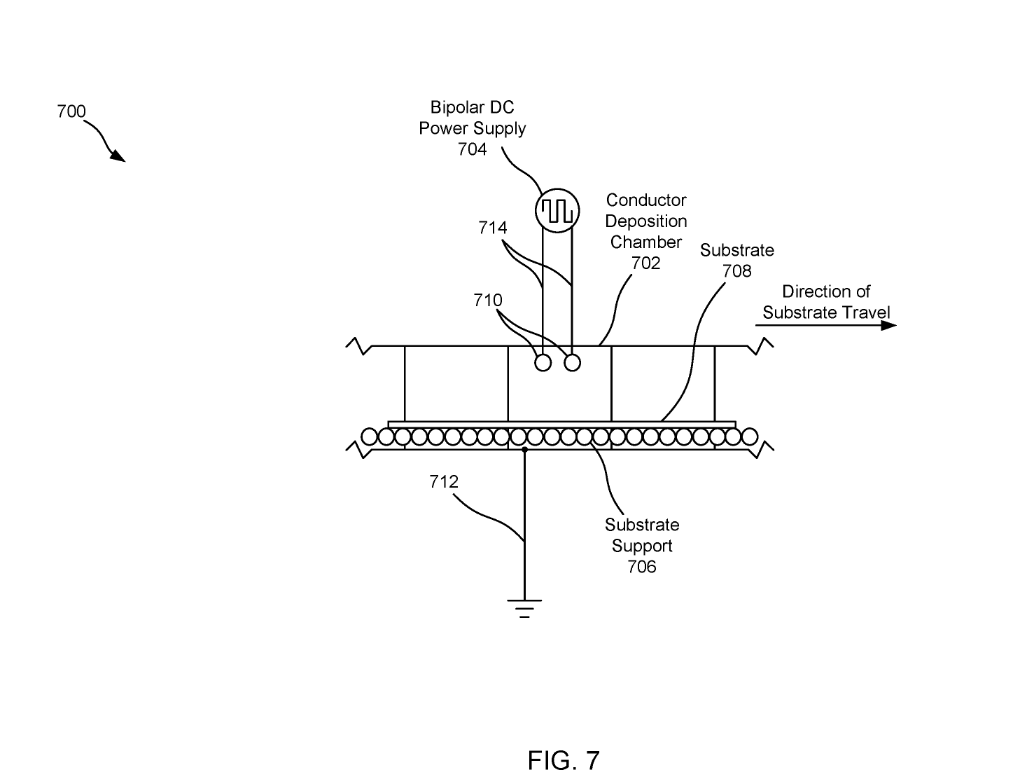

FIG. 7 illustrates a subsection of a substrate coating system 700 having a plurality of deposition chambers arranged in a processing line, where the instant substrate coating system 700 includes at least one deposition chamber for sputtering a conductor. The conductor deposition chamber 702 is coupled to a bipolar DC power supply 704 (such as the AMS-DMS combination of units manufactured by Advanced Energy, Fort Collins, Colo.). The system 700 also shows two other non-defined deposition chambers on either side of the conductor deposition chamber 702 that can be configured to deposit insulators, conductors, or other materials. System 700 includes a substrate support 706, such as conveyor rollers, that is arranged through at least the conductor deposition chamber 702 as well as other chambers in the substrate coating system 700. The substrate support 706 is configured to pass or convey a substrate 708 through at least the conductor deposition chamber 702 as well as other chambers in the system 700 such that the chambers can continuously deposit thin films as the substrate 708 passes through each chamber.

The bipolar DC power supply 704 can be coupled to two electrodes 710 as illustrated. However, in other embodiments, only a single electrode may be implemented. Alternatively, more than two electrodes can be used. As illustrated, the electrodes 710 are floating. In other embodiments, one of the electrodes can be coupled to the chamber 702 or to ground such that the cathode is referenced to ground rather than the floating arrangement that is illustrated. The bipolar DC power supply 704 can be coupled to and provide power to the electrodes 710 via connections 714. The connections 714 can be embodied in a single cable, such as a coaxial cable or a triaxial cable, or in pairs of cables, wires, or leads.

For purposes of this disclosure, the bipolar DC power supply 704 is a type of AC power supply. The bipolar DC power supply 704 can also be referred to as a bi-polar or switched DC power supply. In an embodiment, the bipolar DC power supply 704 can be embodied by a power modulator arranged on an output of a DC power section in order to produce the required waveform. The bipolar DC power supply 704 can produce a square wave output among others. For instance, the bipolar DC power supply 704 can produce a waveform having two different voltages during each positive voltage cycle and a single negative voltage during each negative voltage cycle, or three different voltages during the negative cycle and two different voltages during the positive cycle (reference to positive and negative cycles is relative since, depending on the reference, the entire bipolar waveform can be above or below zero volts). In other embodiments, the bipolar DC power supply 704 can generate a waveform having short sections of slanted or curved voltage, although sharp rises and falls between cycles typically define such pulsed waveforms. A bipolar waveform can include both positive and negative voltages referenced to ground or referenced to any other reference point. In some cases the bipolar signal may only include positive or may only include negative voltages, depending on the reference point. Also, the magnitude of positive and negative cycles need not be equivalent. For instance, when referenced to ground, positive cycles may have twice the magnitude of negative cycles. The bipolar DC power supply 704 may also vary a duty cycle or period of the positive and negative cycles. For instance, positive cycles may be twice as long as negative cycles.

The bipolar DC power supply 704, connections 714, and electrodes 714 can take any shape, form, and arrangement, as such modifications will not affect the outcome of this disclosure. For instance, the electrodes 710 can be cylindrical or cubic, to name just two non-limiting examples. The electrodes 710 can also be arranged and in contact with sides of the insulator deposition chamber 702, or can be largely separated from the chamber 702 walls as illustrated (of course some support structure that couples to the chamber 702 walls will typically be used, but the majority of the electrodes 710 are not in contact with the chamber 702 in this embodiment).

The bipolar DC power supply 704 is used with the conductor deposition chamber 702 to deposit conductor (or conducting or conductive) material in a conductor thin film on the substrate 708. Given the illustrated chamber position, the conductor film will be deposited above one or more other films and below one or more other films. However, in other embodiments, the conductor deposition chamber and its bipolar DC power supply 704 can be arranged in other positions in the substrate coating system 700, for instance at the front or back of the processing line such that the conductor layer is the bottom or top layer of a thin film stack on the substrate 708.

The bipolar DC power supply 704 and its electrodes 710 are illustrated as electrically floating, or floating, and therefore the voltage on the electrodes 710 and output by the bipolar DC power supply 704 is not referenced to ground. In other embodiments, the bipolar DC power supply 704 can be referenced to ground. The illustrated conductor deposition chamber 702 is grounded via grounding connection 712. Where the chambers in the substrate coating system 700 are conductively coupled, only a single grounding connection 712 for the entire system 700 is needed, although more than this can be implemented.

The substrate support 706 can be grounded, or electrically connected to the chambers or the grounding connection 712. Alternatively, the substrate support 706 can be floating. In this and subsequent figures, the substrate support 706 is assumed to be grounded.

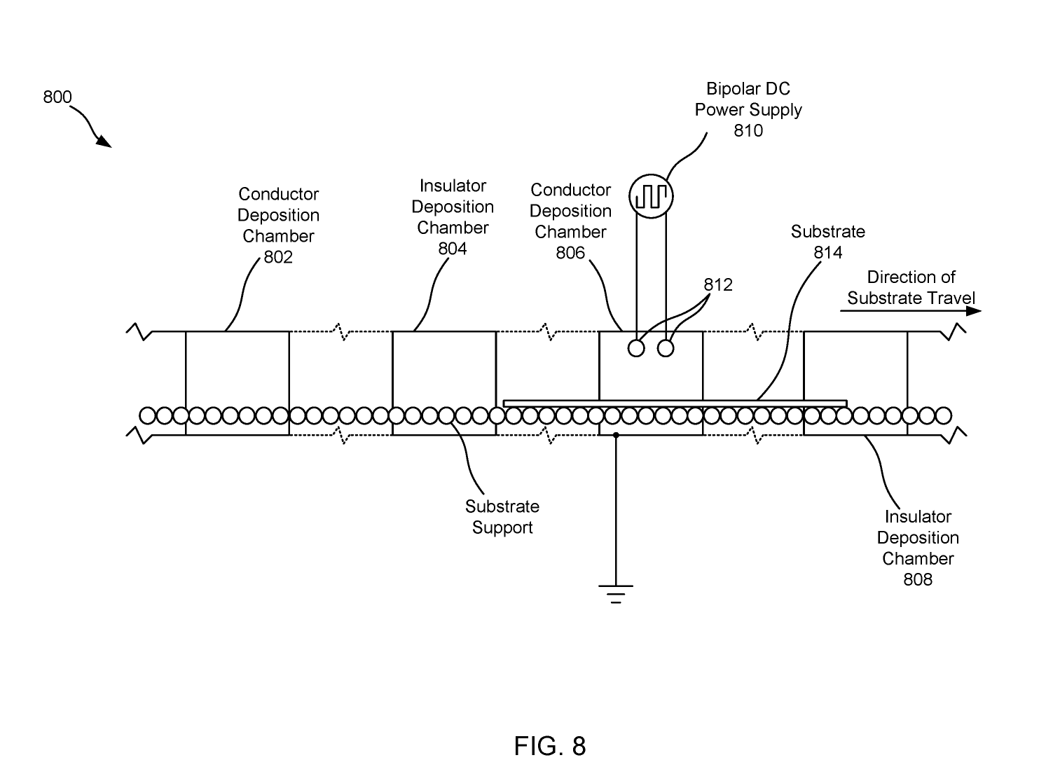

FIG. 8 illustrates another substrate coating system 800 showing one of the many combinations of deposition chambers and arrangements of chambers that can be implemented. The substrate coating system 800 includes two conductor deposition chambers 802, 806 separated by an insulator deposition chamber 804. Also, a further insulator deposition chamber 808 can follow the second conductor deposition chamber 806. The substrate coating system 800 can also optionally include one or more deposition chambers between two or more of those chambers already noted (as indicated by dotted lines). In the illustrated embodiment, the second conductor deposition chamber 806 is coupled to a bipolar DC power supply 810 providing bipolar DC power to electrodes 812. The power supplies for the other chambers in the system 800 are not illustrated, as these can vary (e.g., DC, AC, bipolar DC, etc.).

FIG. 8 also shows one location of a substrate 814 where crazing is likely to occur. In particular, the substrate 814 has passed through the first conductor deposition chamber 802 and the first insulator deposition chamber 804, and is within at least a portion of both the second conductor deposition chamber 806 and the second insulator deposition chamber 810 as well as any intervening chambers and possibly one or more chambers preceding the second conductor deposition chamber 806. One can see that this means that at least two conductor layers have been deposited on the substrate 814 separated by at least one insulator layer, and that a further insulator layer atop the second of the two conductor layers has started to be deposited. As a result, power from a power supply of the second insulator deposition chamber 808 is able to couple through the glass to another power supply, such as a DC power supply to the left of the bipolar DC power supply 810 (if one is used), which may result in crazing.

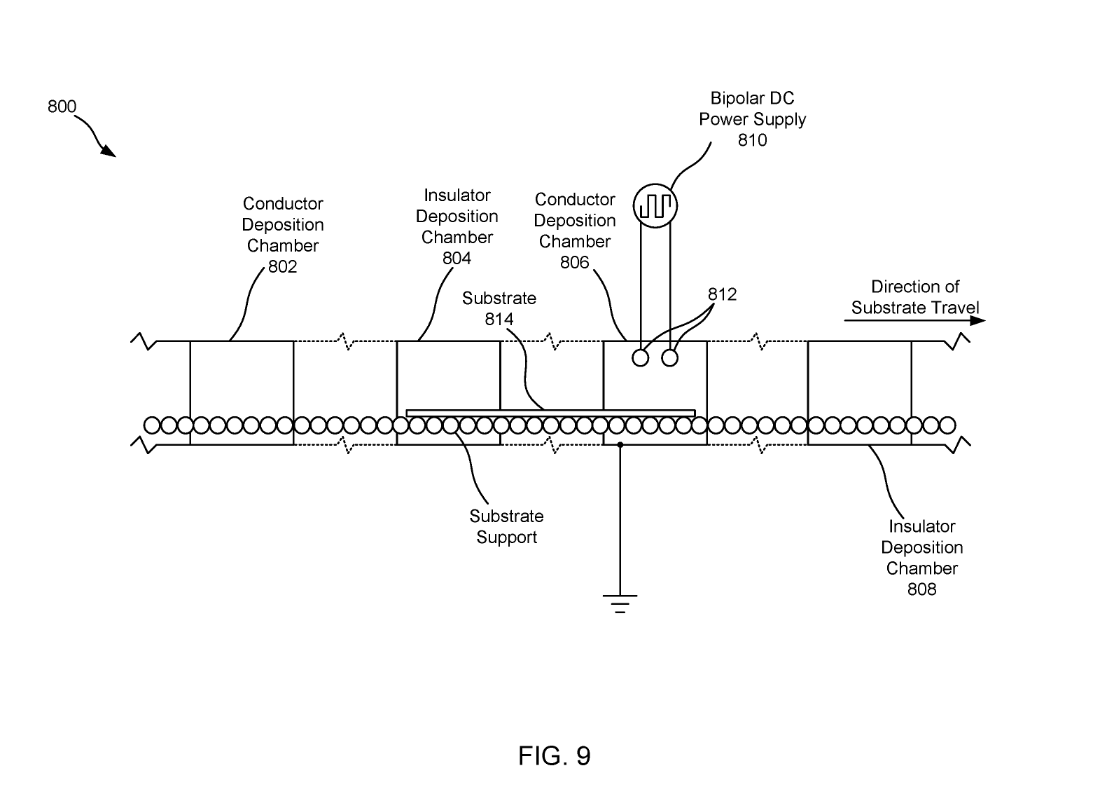

FIG. 9 shows the system 800 of FIG. 8 with the substrate 814 in an alternative position that has been known to lead to crazing. Here, the substrate 814 spans at least the first insulator deposition chamber 804 and the second conductor deposition chamber 806. As seen, this substrate 814 has at least first and second conductor layers separated by at least one insulator layer. In other words, once the equivalent of a capacitor has been formed on the substrate 814, crazing has been known to occur.

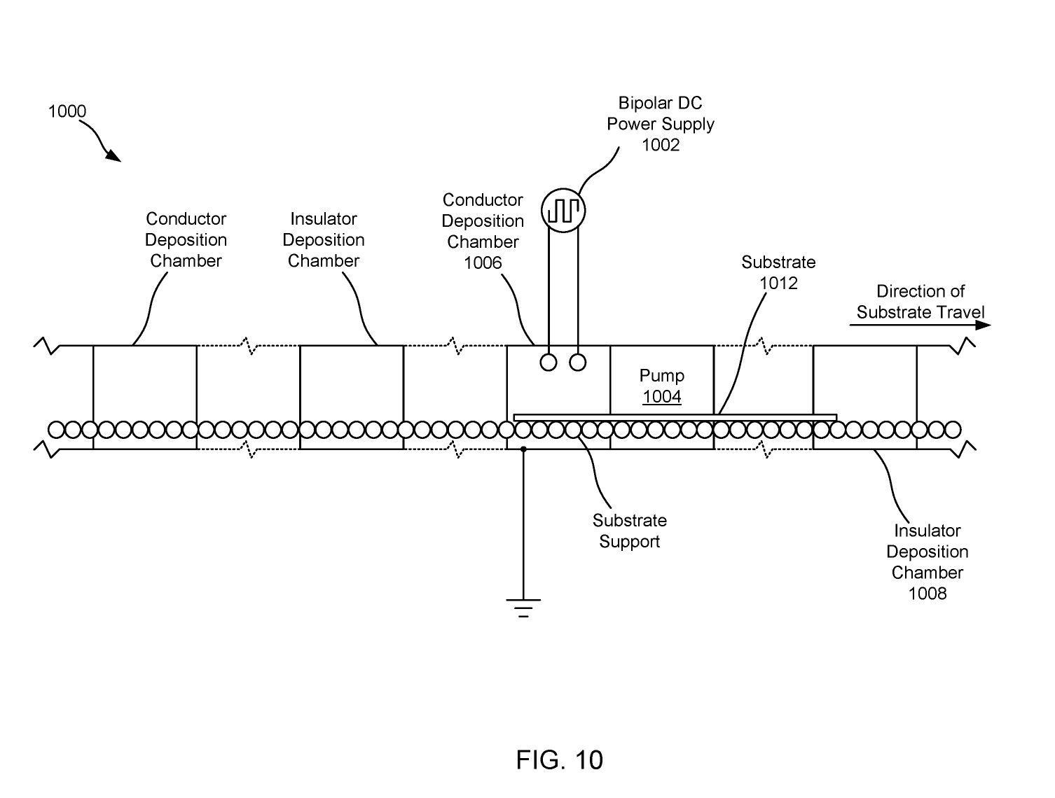

FIG. 10 illustrates another substrate coating system 1000 having a plurality of deposition chambers, a bipolar DC power supply 1002 for helping to deposit conductor, and a pump 1004 adjacent to a chamber with the bipolar DC power supply 1002. Typically one or more pumps 1004 are interspersed throughout the substrate coating system 1000 or within the deposition chambers themselves, in order to remove exhaust gases, such as spent nitrogen or argon. Here, a pump 1004 is arranged adjacent to a conductor deposition chamber 1006 having a bipolar DC power supply 1002. Further, the substrate 1012 can experience crazing when it spans the conductor deposition chamber 1006, the pump 1004, and an insulator deposition chamber 1008 that is arranged downstream of the pump.

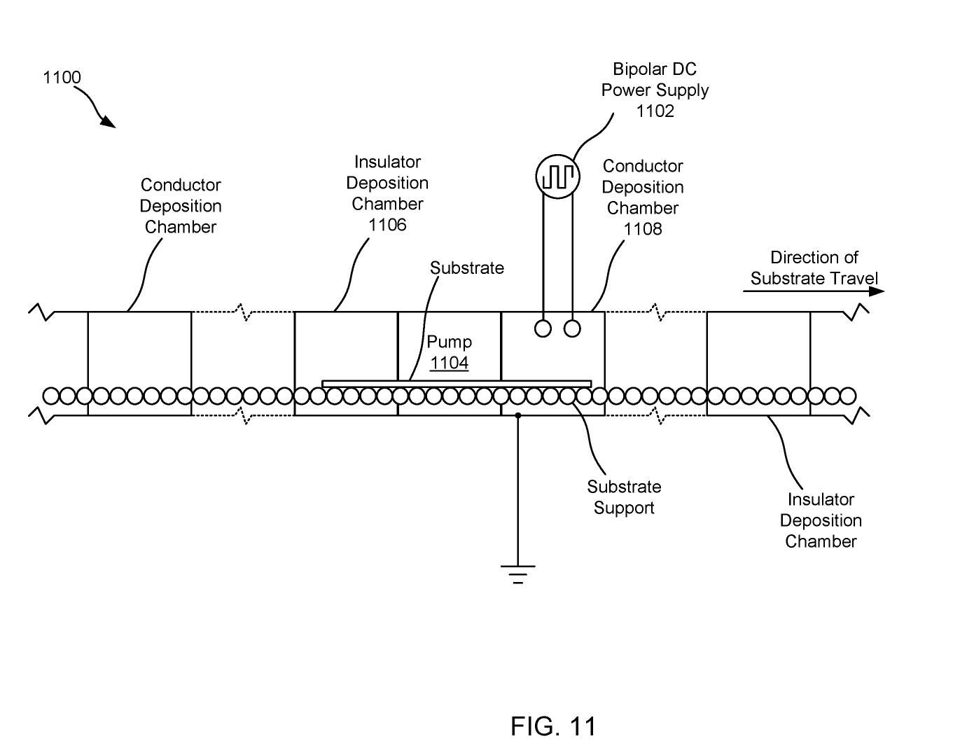

FIG. 11 illustrates yet another substrate coating system 1100 having a plurality of deposition chambers, a bipolar DC power supply 1102 for helping to deposit conductor, and a pump 1104 adjacent to a chamber with the bipolar DC power supply 1102. Here, the pump resides between an insulator deposition chamber 1106 and a conductor deposition chamber 1108 having the bipolar DC power supply 1102. Further, the substrate 1110 can experience crazing when it spans the insulator deposition chamber 1106, the pump 1104, and the conductor deposition chamber 1108.

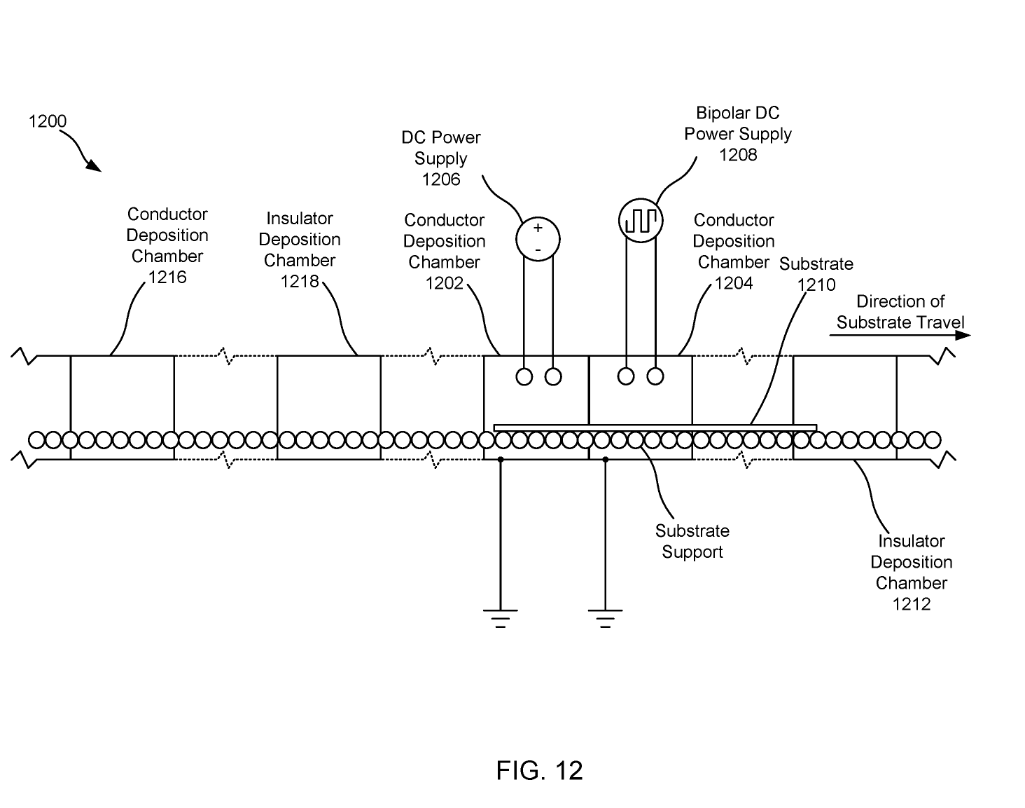

FIG. 12 illustrates yet another substrate coating system 1200 having a plurality of deposition chambers. Among these chambers are a first conductor deposition chamber 1202 and a second conductor deposition chamber 1204. The first conductor deposition chamber 1202 is coupled to a DC power supply 1206 and the second conductor deposition chamber 1204 is coupled to a bipolar DC power supply 1208. Such a configuration is sometimes used where two different metal layers are deposited adjacent to each other in the thin film stack. One can see that the first and second conductor deposition chambers 1202, 1204 are not the lowermost conductor layers in the thin film stack, as at least one other conductor layer was deposited earlier (third conductor deposition chamber 1216). Thus, the layers deposited by the combination of the third conductor deposition chamber 1216 and either or both of the first and second conductor deposition chambers 1202, 1204, separated by the second insulator deposition chamber 1218, act like a capacitor and can lead to crazing.

Some believe that coupling between an AC power supply coupled to the insulator deposition chamber 1212 or 1218 and a floating anode of the DC power supply 1206 causes an anode fall below ground that charges the capacitor formed in the thin film stack. This anode fall and subsequent charging of the capacitor causes breakdown of the insulator between the conductor layers and hence crazing.

This figure also shows a substrate 1210 in a position spanning the first conductor deposition chamber 1202, the second conductor deposition chamber 1204, and a first insulator deposition chamber 1212 that follows the second conductor deposition chamber 1204. Crazing is sometimes seen when the substrate 1210 reaches this position in the substrate coating system 1200. One or more additional deposition chambers can be arranged between the second conductor deposition chamber 1204 and the first insulator deposition chamber 1212.

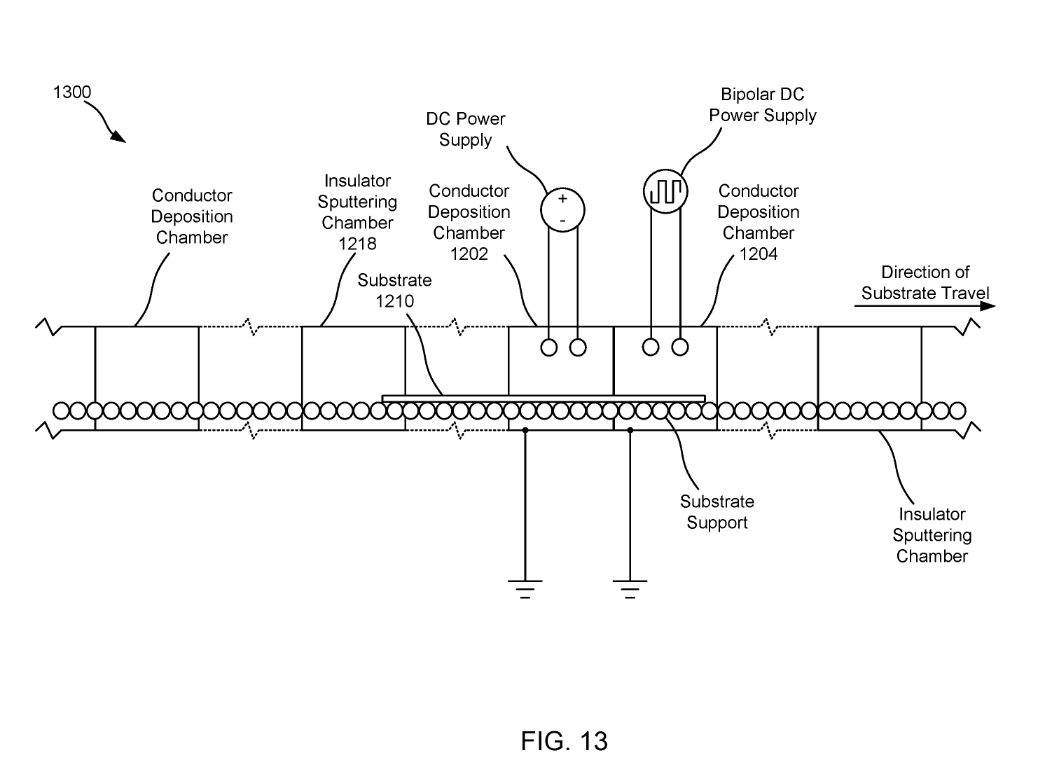

FIG. 13 shows the substrate coating system 1200 of FIG. 12, but where the substrate 1210 is in an earlier position in the substrate coating system 1200 where crazing is often observed. In particular, the substrate 1210 spans the second insulator deposition chamber 1218 and the first and second conductor deposition chambers 1202, 1204. The second insulator deposition chamber 1218 in this case precedes the first and second conductor deposition chambers 1202, 1204. This is another position of the substrate 1210 where crazing has often been observed. Again, the capacitive effect of conductor-insulator-conductor layers exists once the substrate 1210 is coated by the first conductor deposition chamber 1202.

In both of FIGS. 12 and 13, the first and second conductor deposition chambers 1202, 1204 are grounded, however, any one or more grounding connections for the entire substrate coating systems 1200, 1300 can be used, depending on the demands of the system, and conductive coupling between deposition chambers of the systems 1200, 1300.

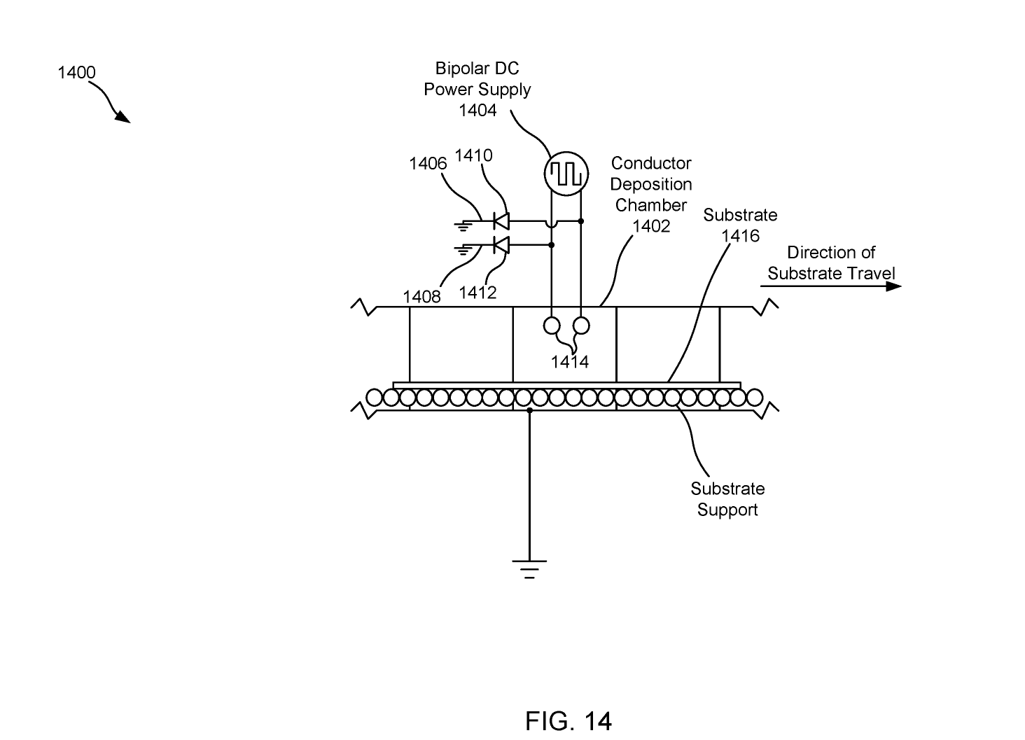

FIG. 14 illustrates a portion of a substrate coating system 1400 having a conduction deposition chamber 1402 coupled to a bipolar DC power supply 1404, wherein the power supply's 1404 outputs (or leads to electrodes 1414 in the chamber 1402) each include a rectified channel to ground 1406, 1408. Each rectified channel to ground 1406, 1408 can include one or more rectifying element, such as diodes 1410, 1412 (although only a single diode per channel 1406, 1408 is illustrated). However, the rectifying elements (e.g., diodes 1410, 1412) could also be implemented as switches configured to prevent a voltage of the electrodes 1414 from falling below 0 V. In other words, the rectified channels to ground are configured to prevent the output of the bipolar DC power supply 1404, or the electrodes 1414, from falling below ground or 0 V. As will be seen in subsequent figures, each of the diodes 1410, 1412 can be replaced by a series of diodes, and the pair of diodes 1410, 1412 illustrated can be replaced by a diode box having two parallel sets of series connected diodes.

The rectified channels to ground 1406, 1408 can couple to outputs of the bipolar DC power supply 1404, including: leads, cables, or power lines connecting the bipolar DC power supply 1404 to electrodes 1414 in the conductor deposition chamber 1402; and the electrodes 1414, to name two non-limiting examples.

In some embodiments, the bipolar DC power supply 1404 can take the form of other types of AC power supplies, and therefore is not limited to bipolar DC supplies.

The substrate coating system 1400 can include any number of additional deposition chambers to the left and/or right of the conductor deposition chamber 1402. Crazing can occur where a conductor layer and an insulator layer above the conductor layer have been deposited below the conductor layer deposited by the conductor deposition chamber 1402.

The rectified channels to ground 1406, 1408 were implemented on the output of the bipolar DC power supply 1404 despite common industry understanding that doing so leads to even worse crazing. Unexpectedly, the use of the rectified channels to ground 1406, 1408 on a bipolar DC power supply 1404, drastically reduced if not eliminated crazing of thin films on the substrate 1416.

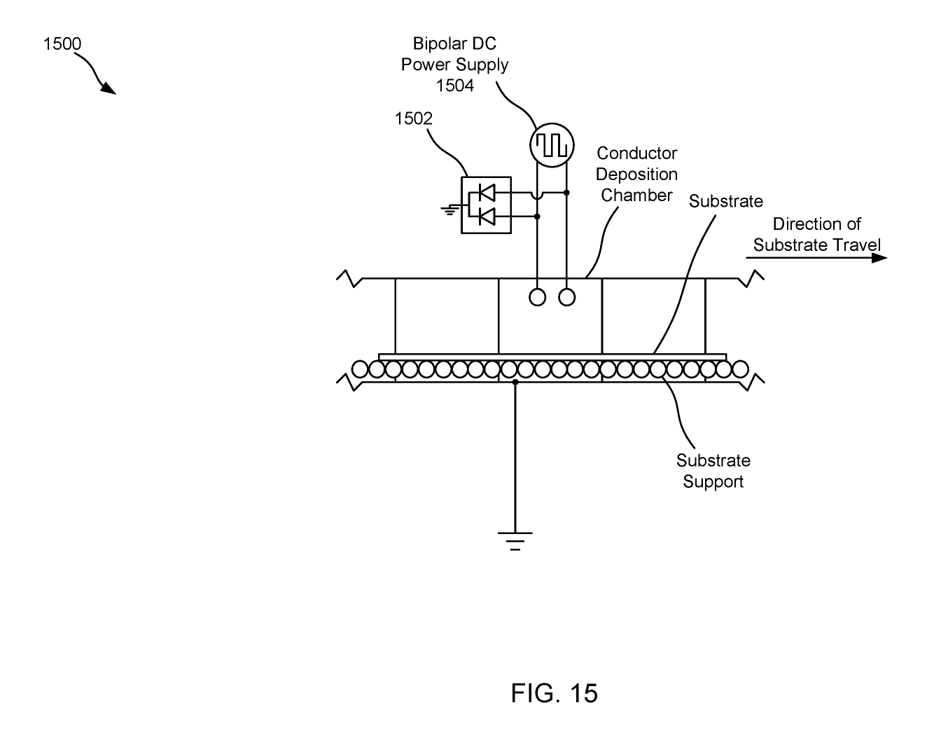

FIG. 15 illustrates an alternative embodiment of the rectified channels to ground seen in FIG. 14. Here, the rectified channels to ground are embodied in a diode box 1502. The diode box 1502 has two inputs coupled to the outputs of the bipolar DC power supply 1504. The diode box 1502 also has an output to ground. However, these inputs and output are functional only and not intended to show limits on the structural implementations of the disclosure. For instance, the two inputs can be in the form of a single coaxial cable or triaxial cable or other cable capable of carrying two channels of power. Also, the single output to ground can be implemented as a two or more cables or leads coupling to ground.

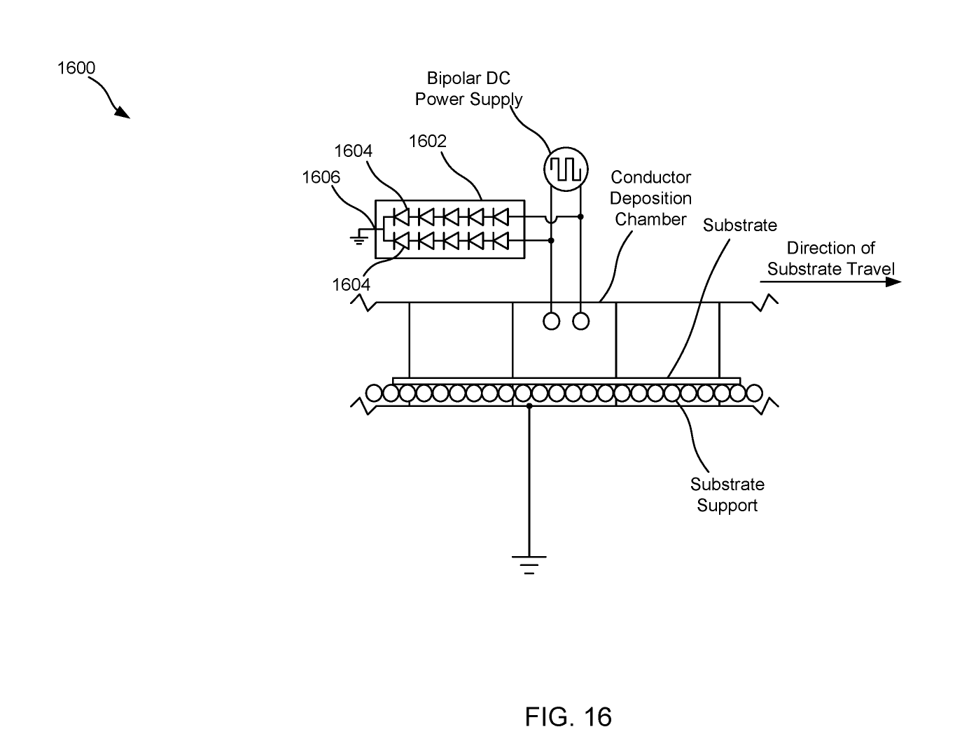

The diode box 1502 can include two channels therein, each corresponding to and connected to one of the outputs of the bipolar DC power supply 1504. Each channel can include a rectifying element, such as a diode or switch. In some embodiments, a set of diodes coupled in series can be implemented for each channel (e.g., see FIG. 16). Where sets of diodes coupled in series are implemented, the diodes in each set can have the same resistance, or can have varying resistance. The use of multiple diodes in series enables the diode box 1502 to handle greater amounts of current and larger voltage drops without damage to the circuitry of the diode box 1502.

The outputs of the two channels can be coupled into a single output for the diode box 1502.

FIG. 16 illustrates an alternative embodiment of the rectified channels to ground seen in FIGS. 14 and 15. Here, the rectified channels to ground are embodied in a diode box 1602 having two channels, each comprising a set of series-connected diodes 1604 whose anodes face toward a ground connection or an output 1606 of the diode box 1602.

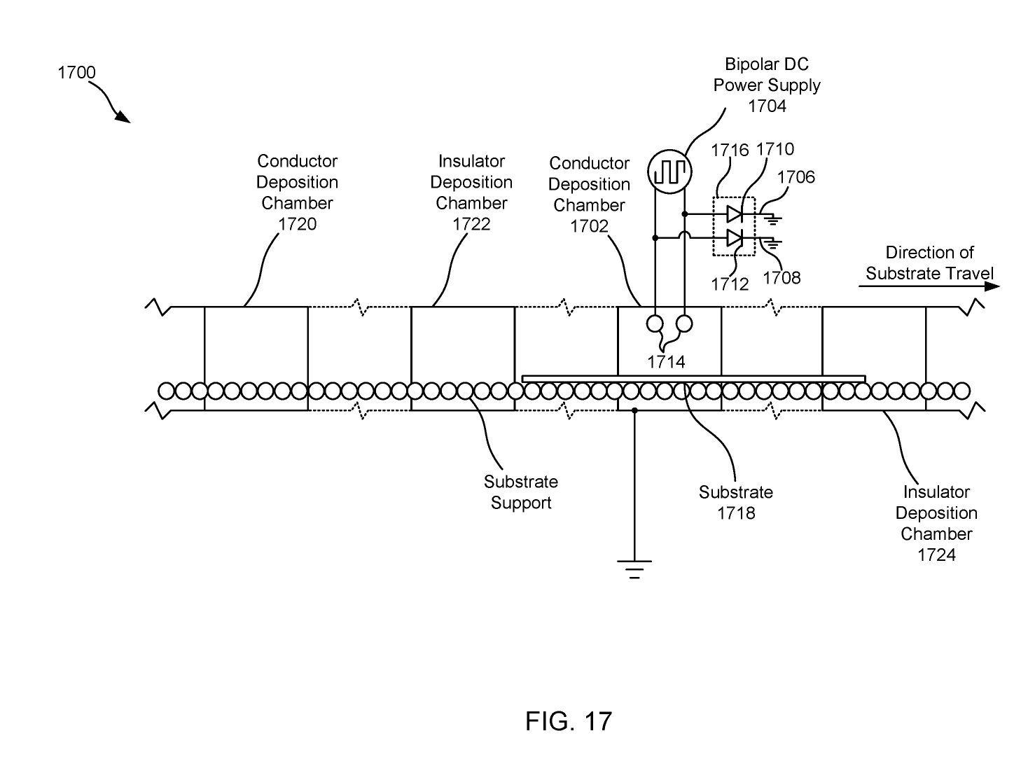

FIG. 17 illustrates another portion of a substrate coating system 1700 having a conduction deposition chamber 1702 coupled to a bipolar DC power supply 1704, wherein the power supply's 1704 outputs (or leads to electrodes 1714 in the chamber 1702) each include a rectified channel to ground 1706, 1708. In one embodiment, the rectified channels to ground 1706, 1708 can include an optional diode box 1716 that may include one or more diodes 1710, 1712 for each of the rectified channels to ground 1706, 1708. In the illustrated embodiment, only a single diode 1710, 1712 per channel is illustrated. However, in other embodiments, the single diodes 1710, 1712 can be implemented as a set of series-connected diodes (e.g., FIG. 16). Also, while the optional diode box 1716 is illustrated as having a pair of outputs, in other embodiments, these ground connections, or outputs, can be implemented as a single ground connection or a single output.

The conductor deposition chamber 1702 is a second of at least two conductor deposition chambers in the substrate coating system 1700, and thus deposits a second conductor layer on the substrate 1718. A first conductor deposition chamber 1720 can deposit a first conductor layer, although additional conductor layers may also have been deposited earlier in the substrate coating system 1700 (to the left of the visible section of the system 1700). Therefore, the conductor deposition chamber 1702 can be referred to as a second conductor deposition chamber 1702.

first insulator deposition chamber 1722 can be arranged between the first and second conductor deposition chambers 1720, 1702, with one or more additional chambers therebetween (as optionally indicated via dotted lines in FIG. 17). A second insulator deposition chamber 1724 can be arranged downstream (to the right of in FIG. 17) of the second conductor deposition chamber 1702. One or more optional chambers can be arranged therebetween as indicated by dotted lines in FIG. 17.

The substrate 1718 and the chambers 1722, 1702, 1724 can be shaped and arranged such that the substrate 1718 spans at least the first insulator deposition chamber 1722 and the second conductor deposition chamber 1702 (a first arrangement where crazing often occurs in the prior art), or spans at least the second conductor deposition chamber 1702 and the second insulator deposition chamber 1724 (a second arrangement where crazing often occurs in the prior art).

Other conductor deposition chambers may be arranged between the first and second insulator deposition chambers 1722, 1724, and may be arranged either upstream (to the left of in FIG. 17) or downstream (to the right of in FIG. 17) the second conductor deposition chamber 1702.

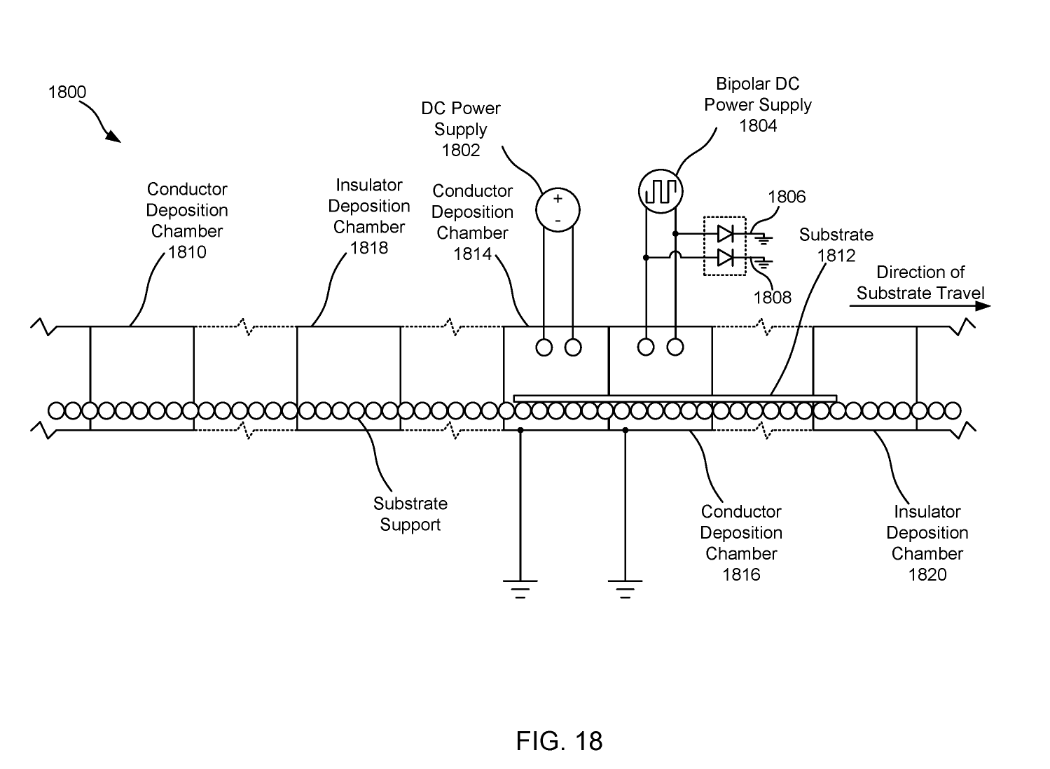

For instance, FIG. 18 illustrates another portion of a substrate coating system 1800 where two conductor deposition chambers are arranged adjacent to each other, the first coupled to a DC power supply 1802, having floating electrodes, and the second coupled to a bipolar DC power supply 1804 having outputs that each include a rectified channel to ground 1806, 1808. A first conductor deposition chamber 1810 can deposit a first conductor layer on a substrate 1812, the second conductor deposition chamber 1814 can deposit a second conductor layer on the substrate 1812 above the first conductor layer, and the third conductor deposition chamber 1816 can deposit a third conductor layer on the substrate 1812 above the second conductor layer. Arranged between the first and second conductor deposition chambers 1810, 1814, and optionally one or more additional chambers indicated by dotted line, can be a first insulator deposition chamber 1818. Downstream of the second conductor deposition chamber 1816, separated therefrom by one or more optional additional chambers, can be a second insulator deposition chamber 1820.

The layering of the first conductor, the first insulator, and the second conductor (or the third conductor) effectively forms a capacitor and thus the formation of these layers can lead to crazing of the substrate 1812. However, the use of the rectified channels to ground 1806, 1808 for each of two outputs of the bipolar DC power supply have been shown to unexpectedly reduce if not eliminate crazing.

The substrate 1812 and the chambers 1810, 1814, 1816 can be shaped and arranged such that the substrate 1812 spans at least the first insulator deposition chamber 1818 and the second conductor deposition chamber 1814 (a first arrangement where crazing often occurs in the prior art), or spans at least the third conductor deposition chamber 1804 and the second insulator deposition chamber 1820 (a second arrangement where crazing often occurs in the prior art). In some cases, crazing has been known to occur when the substrate 1812 spans at least the first insulator deposition chamber 1818, the second conductor deposition chamber 1814, and the third conductor deposition chamber 1816. Crazing has also been seen in some cases, where the substrate 1812 spans at least the second conductor deposition chamber 1814, the third conductor deposition chamber 1816, and the second insulator deposition chamber 1820.

Other chambers upstream or downstream from those illustrated can also be implemented.

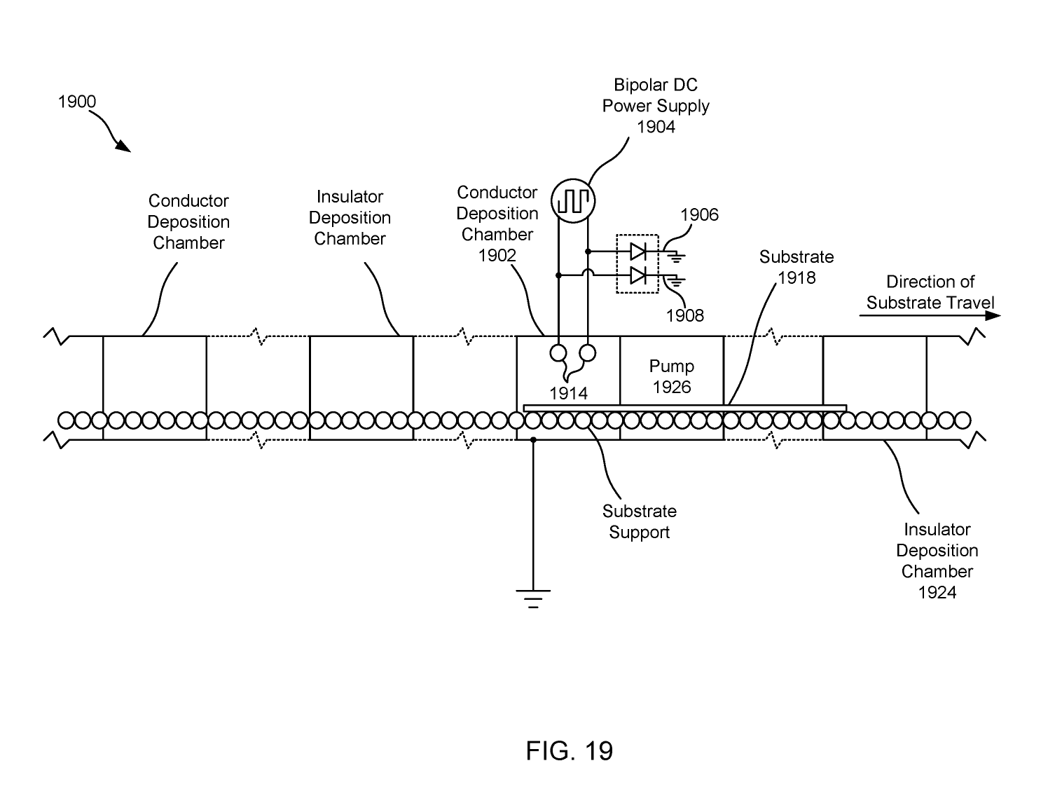

FIG. 19 illustrates another portion of a substrate coating system 1900 having a conduction deposition chamber 1902 coupled to a bipolar DC power supply 1904, wherein the power supply's 1904 outputs (or leads to electrodes 1914 in the chamber 1902) each include a rectified channel to ground 1906, 1908. All other descriptions of FIG. 19 are identical to FIG. 17, with the exception that FIG. 19 further includes a pump 1926 between the conductor deposition chamber 1902 and the insulator deposition chamber 1924. In the illustrated embodiment, the pump 1926 is adjacent to the conductor deposition chamber 1902, although in other implementations it can be arranged anywhere between the conductor deposition chamber 1902 and the insulator deposition chamber 1924.

Crazing has often been seen where the substrate 1918 spans at least the conductor deposition chamber 1902, the pump 1926, and the insulator deposition chamber 1924. However, implementation of the two rectified channels to ground 1906, 1908 was seen to drastically reduce if not eliminate crazing of the substrate 1918.

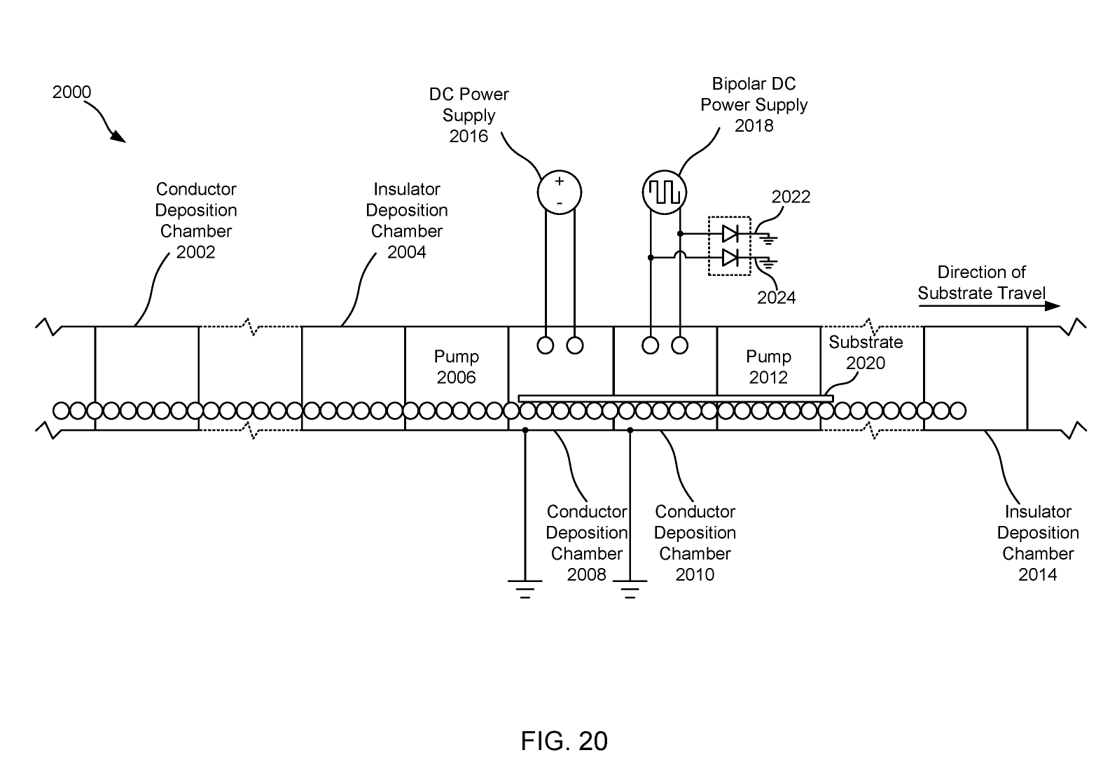

FIG. 20 illustrates another portion of a substrate coating system 2000 having a first conductor deposition chamber 2002, a first insulator deposition chamber 2004, a pump 2006, a second conductor deposition chamber 2008, a third conductor deposition chamber 2010, a second pump 2012, and a second insulator deposition chamber 2014. A DC power supply 2016, having floating electrodes, is coupled to the second conductor deposition chamber 2008 and a bipolar DC power supply 2018 is coupled to the third conductor deposition chamber 2010.

The second and third conductor deposition chambers 2008, 2010 can be arranged adjacent to each other. The first conductor deposition chamber 2002 can be arranged upstream of the second and third conductor deposition chambers 2008, 2010, and the first insulator deposition chamber 2004 can be arranged therebetween with optional one or more chambers between the first insulator deposition chamber 2004 and the first conductor deposition chamber 2002. The first pump 2006 can be arranged between the first insulator deposition chamber 2004 and the second conductor deposition chamber 2008. The second pump 2012 can be arranged between the third conductor deposition chamber 2010 and the second insulator deposition chamber 2014.

The chambers 2004, 2008, 2010, 2014 and the substrate 2020 can be sized and arranged such that the substrate 2020 spans at least the first insulator deposition chamber 2004, the first pump 2006, and the second conductor deposition chamber 2008, as well as any optional intervening chambers indicated by the dotted lines (a first situation in which crazing was often seen in the prior art). They can also be sized and arranged such that the substrate 2020 spans at least the first insulator deposition chamber 2004, the first pump 2006, the second conductor deposition chamber 2008, and the third conductor deposition chamber 2010, as well as any optional intervening chambers indicated by the dotted lines (a second situation in which crazing was often seen in the prior art). They can also be sized and arranged such that the substrate 2020 spans at least the third conductor deposition chamber 2010, the second pump 2012, and the second insulator deposition chamber 2014, as well as any optional intervening chambers indicated by the dotted lines (a third situation in which crazing was often seen in the prior art). They can also be sized and arranged such that the substrate 2020 spans at least the second conductor deposition chamber 2008, the third conductor deposition chamber 2010, the second pump 2012, and the second insulator deposition chamber 2014, as well as any optional intervening chambers indicated by the dotted lines (a fourth situation in which crazing was often seen in the prior art).

Although crazing has often been seen in the prior art when the substrate 2020 is sized and arranged as indicated above, with the implementation of a rectified channel to ground 2022, 2024 for each of two outputs of the bipolar DC power supply 2018, crazing has been drastically reduced if not eliminated.

Although the two rectified channels to ground 2022, 2024 are illustrated as being implemented as an optional diode box having two channels, each comprising a single diode, in other embodiments, the two rectified channels to ground 2022, 2024 can be implemented as a diode box having two sets of series-connected diodes, one for each of the two rectified channels to ground.

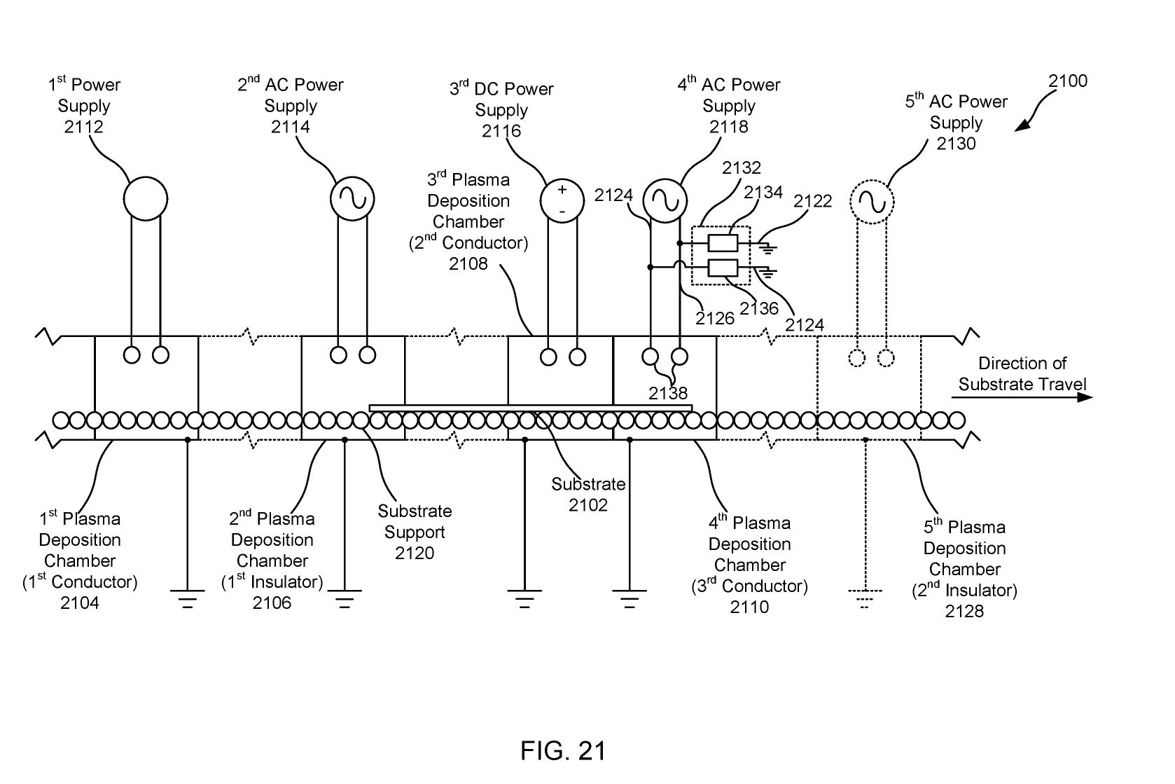

FIG. 21 illustrates a substrate coating system 2100 to reduce crazing of thin films deposited on a substrate 2102 via plasma deposition in a series of plasma deposition chambers. The system 2100 can include a first plasma deposition chamber 2104, a second plasma deposition chamber 2106, a third plasma deposition chamber 2108, a fourth plasma deposition chamber 2110, a first power supply 2112, a second AC power supply 2114, a third DC power supply 2116, a fourth AC power supply 2118, a substrate support 2120, a first rectified channel to ground 2122, and a second rectified channel to ground 2124. The electrodes of the third DC power supply 2116 can be floating.

The first plasma deposition chamber 2112 can be configured to deposit a first conductor onto the substrate 2102. The second plasma deposition chamber 2104 can be configured to deposit an insulator onto the substrate one or more layers above the first conductor. The third plasma deposition chamber 2106 can be configured to deposit a second conductor onto the substrate 2102 one or more layers above the insulator. The fourth plasma deposition chamber 2110 can be configured to deposit a third conductor onto the substrate one or more layers above the second conductor. The first power supply 2112 can be coupled to the first plasma deposition chamber 2104. The second AC power supply can be coupled to the second plasma deposition chamber 2106. The third DC power supply 2116 can be coupled to the third plasma deposition chamber 2108. The fourth AC power supply 2118 can be coupled to the fourth plasma deposition chamber 2110. The substrate support 2120 can be arranged through the first, second, third, and fourth plasma deposition chambers 2104, 2106, 2108, 2110 and configured to move the substrate 2102 through the substrate coating system 2100 while at least two of the first, second, third, and fourth plasma deposition chambers 2104, 2106, 2108, 2110 simultaneously deposit respective ones of the first conductor, the insulator, the second conductor, and the third conductor on the substrate 2102. The first rectified channel to ground 2122 can be coupled between a first output 2124 of the fourth AC power supply 2118 and ground. The second rectified channel to ground 2124 can be coupled between a second output 2126 of the fourth AC power supply 2118 and ground.

The first power supply 2112 need not be limited to any particular type of supply (e.g., AC, DC, bipolar DC, etc.) and hence can deposit any number of different layers on the substrate 2102. However, in one embodiment, the first power supply 2112 is configured to assist in deposition of a first conductor layer on the substrate 2102. In an embodiment, the fourth AC power supply 2118 can be a bipolar DC power supply. In an embodiment, the rectified channels to ground 2122, 2124 can be embodied in a diode box 2132 or other device that provides rectified channels to an output. The optional diode box 2132 can have a single output to ground, although it's illustrated as having two outputs to ground. The optional diode box 2132 may comprise one rectifying element or rectifying circuit 2134, 2136 per rectified channel to ground. In some embodiments, each of the rectifying elements or rectifying circuits 2134, 2136 can include one or more diodes connected in series. In other words, each of the rectified channels to ground 2122, 2124 can comprise a string of one or more diodes, optionally within a diode box.

In an embodiment, the first and second outputs 2124, 2132 of the fourth AC power supply 2118 can include one or more power cables or one or more electrodes 2138 coupled to the fourth AC power supply 2118.

One or more of the chambers 2104, 2106, 2108, 2110, 2128 can have a grounding connection or be coupled to each other or in some other fashion be grounded. In other words, the grounding symbols in FIG. 21 are representative of electrical properties rather than required structure, since various structure well-known to those of skill in the art can be implemented to enable grounding of the chambers 2104, 2106, 2108, 2110, 2128.

Optionally, the system 2100 can include a fifth plasma deposition chamber 2128 coupled to a fifth AC power supply 2130 and depositing a second insulator layer above the third conductor layer. Additional chambers may exist upstream and/or downstream of those illustrated in FIG. 21.

Optionally one or more additional chambers may reside between the first plasma deposition chamber 2104 and the second plasma deposition chamber 2106. Optionally, one or more additional chambers may reside between the second plasma deposition chamber 2106 and the third plasma deposition chamber 2116. Optionally, one or more additional chambers may reside between the fourth plasma deposition chamber 2110 and the optional fifth plasma deposition chamber 2128.

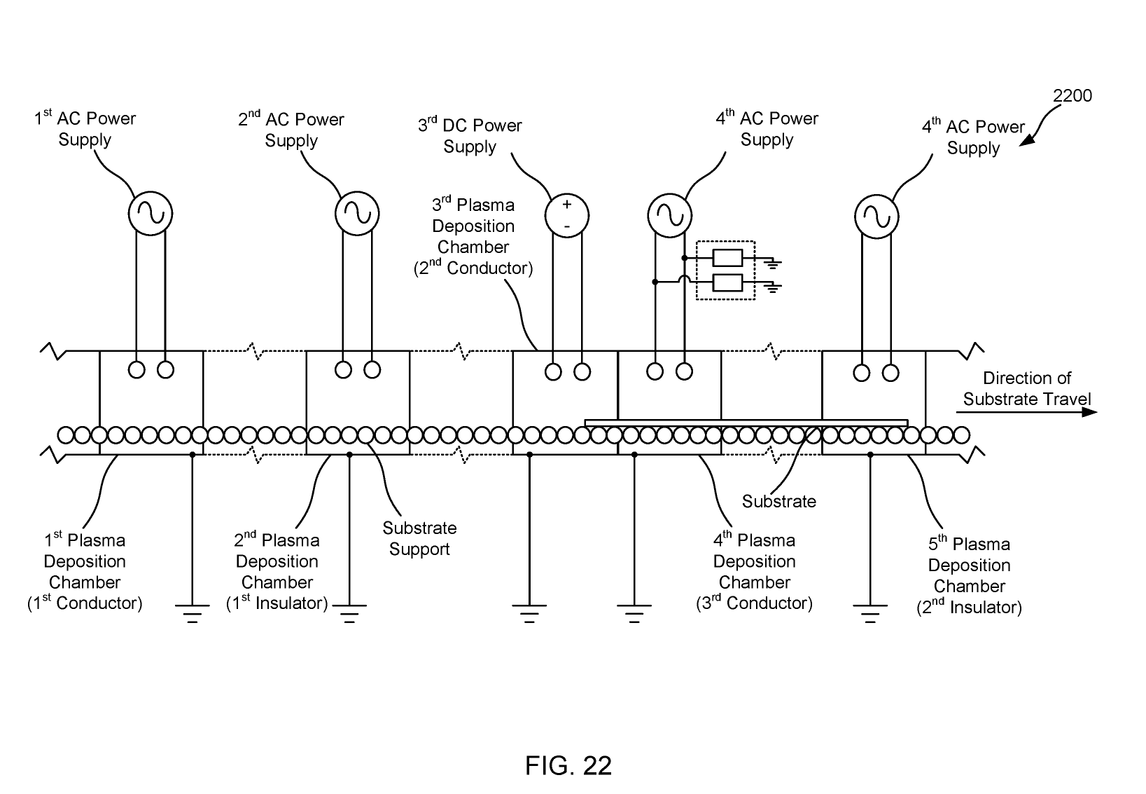

Without the rectified channels to ground 2122, 2124, the thin films deposited on the substrate 2102 can see crazing, especially where the substrate 2102 spans at least the second plasma deposition chamber 2106 and the third plasma deposition chamber 2108 and any other optional intervening chambers. Crazing has also been observed where the substrate 2102 spans at least the second plasma deposition chamber 2106 and the fourth plasma deposition chamber 2110, and any other optional intervening chambers. Yet crazing has also been observed where the substrate 2102 spans at least the fourth plasma deposition chamber 2110 and the optional fifth plasma deposition chamber 2128, and any other optional intervening chambers (see FIG. 22). Crazing has also been observed where the substrate 2102 spans at least the third plasma deposition chamber 2108 and the optional fifth plasma deposition chamber 2128, and any other optional intervening chambers (see FIG. 22). Typically all these scenarios include at least one conductor-insulator-conductor arrangement of layers to be formed, thus effectively creating a capacitor in the thin film stack. With the use of the pair of rectified channels to ground 2122, 2124, the previously-unmitigated crazing has been drastically reduced if not eliminated.

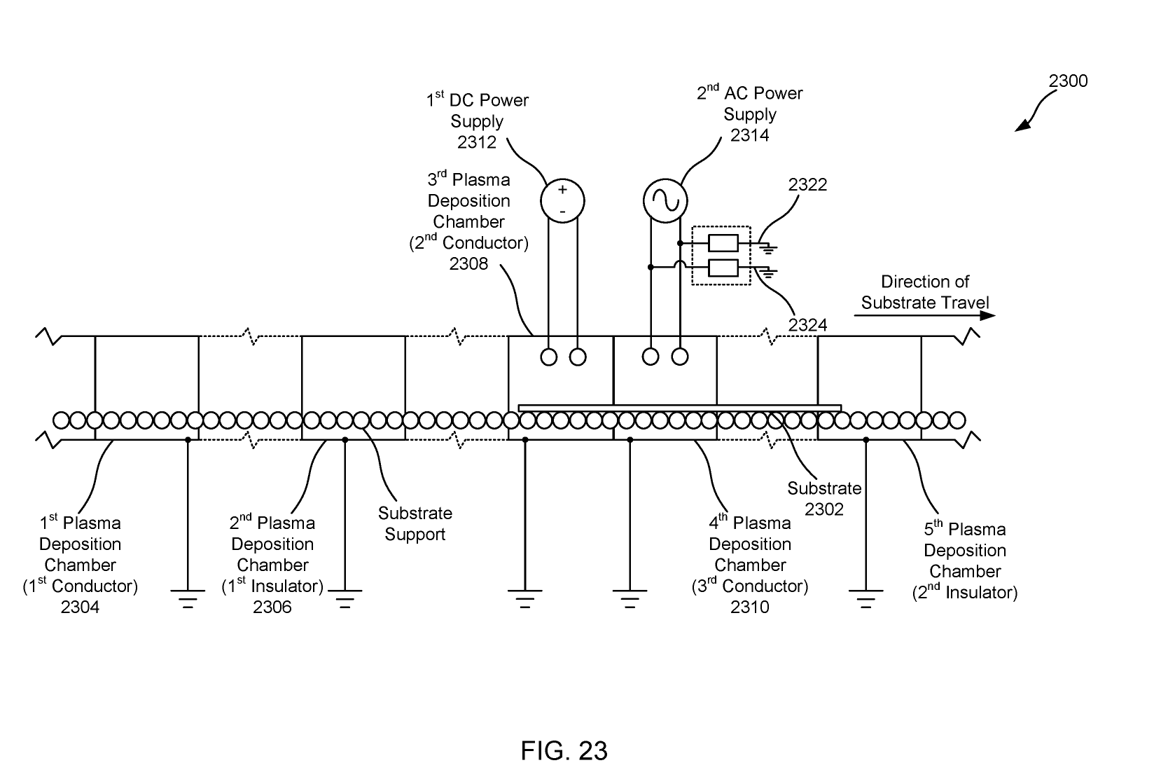

FIG. 23 illustrates a substrate coating system 2300 to reduce crazing of thin films deposited on a substrate 2302 via plasma deposition in a series of plasma deposition chambers. The system 2300 can include a first plasma deposition chamber 2304, a second plasma deposition chamber 2306, a third plasma deposition chamber 2308, a fourth plasma deposition chamber 2310, a first DC power supply 2312, a second AC power supply 2314, a substrate support 2320, a first rectified channel to ground 2322, and a second rectified channel to ground 2324.

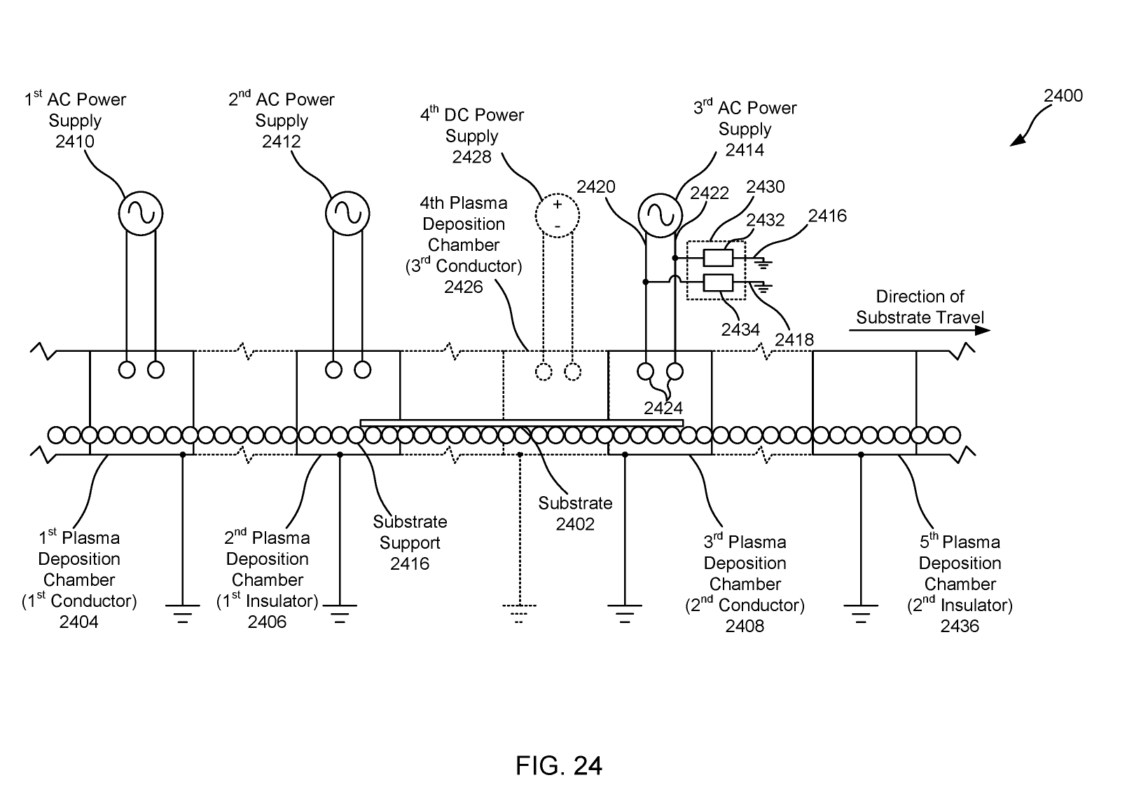

FIG. 24 illustrates another portion of a substrate coating system 2400. The system 2400 is configured to reduce crazing of thin films deposited on a substrate 2402 via plasma deposition in a series of plasma deposition chambers. The system 2400 can include a first plasma deposition chamber 2404, a second plasma deposition chamber 2406, a third plasma deposition chamber 2408, a first power supply 2410, a second AC power supply 2412, a third AC power supply 2414, a first rectified channel to ground 2416, and a second rectified channel to ground 2418.

The first plasma deposition chamber 2404 can be configured to deposit a first conductor onto the substrate 2402. The second plasma deposition chamber 2406 can be configured to deposit an insulator onto the substrate 2402 one or more layers above the first conductor. The third plasma deposition chamber 2408 can be configured to deposit a second conductor onto the substrate 2402 one or more layers above the insulator. The first power supply 2410 can be coupled to the first plasma deposition chamber 2404. The second AC power supply 2412 can be coupled to the second plasma deposition chamber 2406. The third AC power supply 2414 can be coupled to the third plasma deposition chamber 2408. The first rectified channel to ground 2416 can be coupled between a first output 2420 of the third AC power supply 2414 and ground, and the second rectified channel to ground 2418 can be coupled between a second output 2422 of the third AC power supply 2414 and ground.

In an embodiment, the substrate coating system 2400 can further include an optional fourth plasma deposition chamber 2426 between the second plasma deposition chamber 2406 and the third plasma deposition chamber 2408. An optional fourth DC power supply 2428 can be coupled to the optional fourth plasma deposition chamber 2426, such that a third conductor can be deposited on the substrate via this chamber 2426 between the first insulator and the second conductor.

The substrate coating system 2400 can also include a fifth plasma deposition chamber 2436 arranged downstream from the third plasma deposition chamber. The fifth plasma deposition chamber 2436 can be configured to deposit a second insulator one or more layers above the second conductor.

The substrate 2402 and the chambers 2404, 2406, 2408, 2426, 2436 can be sized and arranged such that the substrate 2402 spans at least the second plasma deposition chamber 2406 and the third plasma deposition chamber 2408 (a first situation where crazing often occurred without the rectified channels to ground 2416, 2418). Optionally, the substrate 2402 can also span the fourth plasma deposition chamber 2426 along with the second and third plasma deposition chambers 2406, 2408. As a result, the first insulator, the second conductor, and optionally the third conductor, can be simultaneously deposited on the substrate 2402 for at least a moment in time.

The substrate 2402 and the chambers 2404, 2406, 2408, 2426, 2436 can be sized and arranged such that the substrate 2402 spans at least the third plasma deposition chamber 2408 and the fifth plasma deposition chamber 2436 (a second situation where crazing often occurred without the rectified channels to ground 2416, 2418). Optionally, the substrate 2402 can also span the fourth plasma deposition chamber 2426 along with the third and fifth plasma deposition chamber 2408, 2436. As a result, the second conductor, the second insulator, and optionally the third conductor, can be simultaneously deposited on the substrate 2402 for at least a moment in time.

In yet a further embodiment, the substrate 2402 and the chambers 2404, 2406, 2408, 2426, 2436 can be sized and arranged such that the substrate 2402 spans, or is within, at least two of the second, third, and fourth plasma deposition chambers 2406, 2408, 2426 for at least one moment as the substrate 2402 moves through the substrate coating system 2400. In yet a further embodiment, the substrate 2402 and the chambers 2404, 2406, 2408, 2426, 2436 can be sized and arranged such that the substrate 2402 spans, or is within, at least two of the third, fourth, and fifth plasma deposition chambers 2408, 2426, 2436 for at least one moment as the substrate 2402 moves through the substrate coating system 2400.

In an embodiment, the third AC power supply 2414 can be a bipolar DC power supply.

In an embodiment, the first and second rectified channels to ground 2416, 2418 can be implemented as an optional diode box 2430. The optional diode box 2430 can include a rectifying element or rectifying circuit 2432, 2434 for each of the rectified channels to ground 2416, 2418. Each of the rectifying elements or rectifying circuits 2432, 2434 can comprise a string of one or more diodes connected in series.

In some embodiments, the outputs 2420, 2422 of the third AC power supply 2414 can include cables or leads to electrodes 2424 in the third plasma deposition chamber. Alternatively, the outputs 2420, 2422 can include the electrodes 2424. Where a cable or cables are used, the two outputs 2420, 2422 can form a single cable, for instance a coaxial cable or triaxial cable, or two or more separate cables. While only two electrodes 2424 are illustrated, two or more electrodes 2424 providing power to a plasma within the third plasma deposition chamber, can be realized.

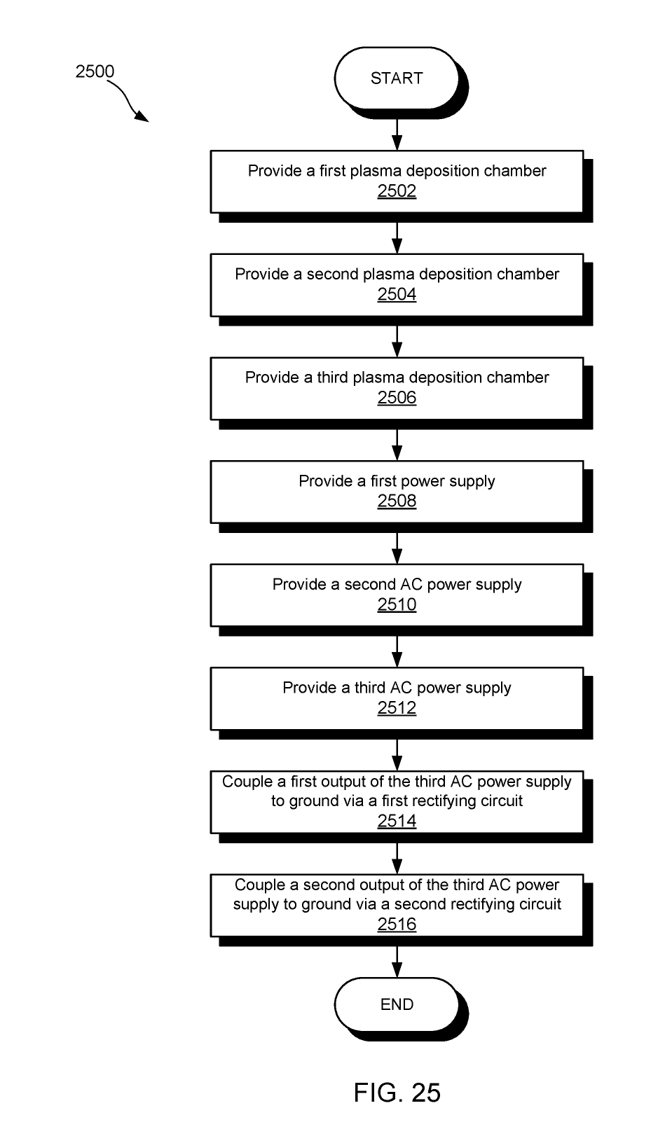

FIG. 25 illustrates a method of reducing crazing of thin films during processing in a substrate coating system, such as those described above. The method 2500 can include providing a first plasma deposition chamber configured to deposit a first conductor onto the substrate (Block 2502). The method 2500 can further include providing a second plasma deposition chamber configured to deposit an insulator onto the substrate one or more layers above the first conductor (Block 2504). The method 2500 can further include providing a third plasma deposition chamber configured to deposit a second conductor onto the substrate one or more layers above the insulator (Block 2506). The method 2500 can further include providing a first power supply coupled to the first plasma deposition chamber (Block 2508). The method 2500 can further include providing a second AC power supply coupled to the second plasma deposition chamber (Block 2510). The method 2500 can further include providing a third AC power supply coupled to the third plasma deposition chamber (Block 2512). The method 2500 can yet further include coupling a first output of the third AC power supply to ground via a first rectifying circuit, such as a diode or series of diodes (Block 2514). The method 2500 can yet further include coupling a second output of the third AC power supply to ground via a second rectifying circuit (Block 2516).

In this way, the method 2500 precludes the first and second outputs of the third AC power supply from being pulled lower than ground potential or 0V. By precluding this, the use of the rectifying circuits also prevents a capacitive charge within the thin film stack from causing breakdown to the insulator layer between the first and second conductor layers and hence crazing.

FIG. 26A illustrates a voltage waveform measured on a floating anode of a DC power supply in a substrate processing system that does not use the rectifying channels to ground discussed in this disclosure. FIG. 26B illustrates a voltage waveform measured on a floating cathode of a DC power supply in a substrate processing system that does not use the rectifying channels to ground discussed in this disclosure. As seen, the floating anode is coupled to an AC waveform from another plasma deposition chamber, for instance one of the AC waveforms used by an AC power supply in a nearby plasma deposition chamber for depositing an insulator. For instance, the floating anode and cathode could be coupled to the DC power supply 1206, 1802, 2016, 2116, 2312, and or 2428, to name a few non-limiting examples, where the rectified channels to ground are not being used. The AC power supply coupling into the floating anode could be AC power supply 2114, 2130, and/or 2412, to name a few non-limiting examples, where the rectified channels to ground are not being used. Once the rectified channels to ground are implemented, the AC waveform see on the floating anode of the DC power supply (FIG. 26A) is reduced if not eliminated, such that the anode and cathode plots are substantially similar.

In an embodiment, the second and third conductors are deposited as adjacent layers, meaning that the second and third plasma deposition chambers can be adjacent in the substrate processing stack.

In an embodiment, the third AC power supply can be a bipolar DC power supply.

In all of the embodiments herein described, the plasma deposition chambers can be implemented using typical plasma deposition components. For instance, one or more electrodes, such as cathodes and/or anodes, can be arranged in the chamber, which receive power from a power supply and form and sustain a plasma in the chamber. Each cathode and/or anode can include a sputtering target, and a magnet array (in the case of magnetron sputtering). Thus, one can describe the above-noted embodiments as having electrodes or magnetrons, depending on the system. Cooling lines within the target can also be employed. Further, the substrate can be supported on a substrate support configured to move the substrate between chambers (e.g., transport rollers for conveying the substrate between chambers).

Co-sputtering is a process in which two or more targets of different composition are sputtered simultaneously (or at substantially the same time). While this disclosure has referenced a pair of outputs coupled to a pair of electrodes within the plasma deposition chambers, where co-sputtering is involved, the pair of outputs may couple to three or more electrodes, or three or more outputs may couple to three or more electrodes.

In an embodiment, a rectified channel to ground (e.g., a diode box or series of diodes) can be coupled to an anode of the DC power supply rather than coupling rectified channels to ground to the outputs of the bipolar DC power supply. For instance, a rectified channel to ground could be coupled between an anode of DC power supply 1802 in FIG. 18 and ground instead of using the rectified channels to ground 1806, 1808. Similar changes could be made, in FIGS. 20-24 such that the elements 2022, 2024, 2132, 2322, 2324, and 2430 can be replaced by a rectified channel to ground attached to an anode of the bipolar DC power supply 2016, 2116, 2312, 2428, and the 3^{rd} DC power supply of FIG. 22.

As used herein, the recitation of “at least one of A, B and C” is intended to mean “either A, B, C or any combination of A, B and C.” The previous description of the disclosed embodiments is provided to enable any person skilled in the art to make or use the present disclosure. Various modifications to these embodiments will be readily apparent to those skilled in the art, and the generic principles defined herein may be applied to other embodiments without departing from the spirit or scope of the disclosure. Thus, the present disclosure is not intended to be limited to the embodiments shown herein but is to be accorded the widest scope consistent with the principles and novel features disclosed herein

What is claimed is:

1. A substrate coating system to reduce crazing of thin films deposited on the substrate via plasma deposition in a series of plasma deposition chambers, the substrate coating system comprising:
a first plasma deposition chamber configured to deposit a first conductor onto the substrate;
a second plasma deposition chamber configured to deposit an insulator onto the substrate one or more layers above the first conductor;
a third plasma deposition chamber configured to deposit a second conductor onto the substrate one or more layers above the insulator;
a fourth plasma deposition chamber configured to deposit a third conductor onto the substrate one or more layers above the second conductor;
a first power supply coupled to the first plasma deposition chamber;
a second AC power supply coupled to the second plasma deposition chamber;
a third DC power supply coupled to the third plasma deposition chamber;
a fourth AC power supply coupled to the fourth plasma deposition chamber;
a substrate support arranged throughout the first, second, third and fourth plasma deposition chambers and configured to move the substrate through the substrate coating system while at least two of the first, second, third, and fourth plasma deposition chambers simultaneously deposit respective ones of the first conductor, the insulator, the second conductor, and the third conductor on the substrate;
a first rectified channel to ground coupled between a first output of the fourth AC power supply and the ground; and
a second rectified channel to ground coupled between a second output of the fourth AC power supply and the ground.

2. The substrate coating system of claim 1, wherein the fourth AC power supply is a bipolar DC power supply.

3. The substrate coating system of claim 1, wherein the first and second rectified channels to ground comprise a diode box.

4. The substrate coating system of claim 3, wherein each of the first and second rectified channels to ground comprise a string of one or more diodes.

5. The substrate coating system of claim 1, wherein the first and second outputs of the fourth AC power supply comprise one or more power cables or one or more electrodes coupled to the fourth AC power supply.

6. The substrate coating system of claim 1, wherein the substrate is a glass.

7. The substrate coating system of claim 6, wherein at least one of the first, second, and third conductors is a metal.

8. The substrate coating system of claim 7, wherein the insulator is a dielectric.

9. The substrate coating system of claim 1, wherein the first, second, third, and fourth plasma deposition chambers are sized such that the substrate is within at least three of these chambers for at least one moment as the substrate moves through the substrate coating system.

10. A substrate coating system to reduce crazing of thin films deposited on the substrate via plasma deposition in a series of plasma deposition chambers, the substrate coating system comprising:
a first plasma deposition chamber configured to deposit a first conductor onto the substrate;
a second plasma deposition chamber configured to deposit an insulator onto the substrate one or more layers above the first conductor;
a third plasma deposition chamber configured to deposit a second conductor onto the substrate one or more layers above the insulator;
a first power supply coupled to the first plasma deposition chamber;
a second AC power supply coupled to the second plasma deposition chamber;
a third AC power supply coupled to the third plasma deposition chamber;
a first rectified channel to ground coupled between a first output of the third AC power supply and ground; and
a second rectified channel to ground coupled between a second output of the third AC power supply and ground.

11. The substrate coating system of claim 10, further comprising:
a fourth plasma deposition chamber arranged between the second and third plasma deposition chambers, the fourth plasma deposition chamber configured to deposit a third conductor onto the substrate between the insulator and the second conductor; and
a fourth DC power supply coupled to the fourth plasma deposition chamber.

12. The substrate coating system of claim 11, wherein the second, third, and fourth plasma deposition chambers are sized such that the substrate is within at least two of these chambers for at least one moment as the substrate moves through the substrate coating system.

13. The substrate coating system of claim 10, wherein the third AC power supply is a bipolar DC power supply.

14. The substrate coating system of claim 10, wherein the first and second rectified channels to ground comprise a diode box.

15. The substrate coating system of claim 14, wherein each of the first and second rectified channels to ground comprise a string of one or more diodes.

16. The substrate coating system of claim 10, wherein the first and second outputs of the third AC power supply comprise one or more power cables or one or more electrodes coupled to the third AC power supply.

17. The substrate coating system of claim 10, further comprising a substrate support arranged throughout the first, second, and third plasma deposition chambers and configured to move the substrate through the substrate coating system while at least two of the first, second, and third plasma deposition chambers simultaneously deposit respective ones of the first conductor, the insulator, and the second conductor on the substrate.

18. The substrate coating system of claim 10, wherein the substrate is a glass.

19. The substrate coating system of claim 18, wherein at least one of the first and second third conductors is a metal.

20. The substrate coating system of claim 19, wherein the insulator is a dielectric.

21. A method of reducing crazing of thin films in a substrate coating system, the method comprising:
providing a first plasma deposition chamber configured to deposit a first conductor onto the substrate;
providing a second plasma deposition chamber configured to deposit an insulator onto the substrate one or more layers above the first conductor;
providing a third plasma deposition chamber configured to deposit a second conductor onto the substrate one or more layers above the insulator;
providing a first power supply coupled to the first plasma deposition chamber;
providing a second AC power supply coupled to the second plasma deposition chamber;
providing a third AC power supply coupled to the third plasma deposition chamber;
coupling a first output of the third AC power supply to ground via a first rectifying circuit; and
coupling a second output of the third AC power supply to ground via a second rectifying circuit.

22. The method of claim 21, wherein the AC power supply is a bipolar DC power supply.

23. The method of claim 21, further comprising transferring the substrate through the substrate coating system such that the first AC power supply and a second AC power supply, both configured to assist in deposition of two different materials, are simultaneously interacting with the substrate.

24. The method of claim 23, further comprising transferring the substrate through the substrate coating system such that at least one DC power supply configured to assist in deposition of a conductor, along with the first and second AC power supplies, are simultaneously interacting with the substrate.

25. The method of claim 21, wherein the first rectifying circuit is a diode.

26. The method of claim 25, wherein the first rectifying circuit is a string of series-connected diodes.
